(19) United States
(12) Patent Application Publication
(10) Pub. No.: US 2026/0190544 A1
(43) Pub. Date: Jul. 2, 2026

(54) MICRO LIGHT EMITTING DIODE CHIP, MICRO LIGHT EMITTING DIODE CHIP TRANSFER SUBSTATE, MICRO LIGHT EMITTING DIODE DISPLAY AND XR GLASSES

(71) Applicant: ULDTEC CO., LTD., Sendai-shi (JP)

(72) Inventor: Motonobu TAKEYA, Sendai-shi (JP)

(21) Appl. No.: 18/855,266

(22) PCT Filed: Nov. 17, 2023
(86) PCT No.: PCT/JP2023/041399

§ 371 Date: Oct. 8, 2024

(30) Foreign Application Priority Data
Jul. 27, 2023 (JP) 2023-122138

(51) Int. Cl. H10H 20/813; H10H 20/825; H10H 29/24

(52) U.S. Cl. CPC H10H 20/8132; H10H 20/825; H10H 29/24

(57) ABSTRACT

A micro light emitting diode chip comprises blue light-emitting AlGaInN-based light emitting diode structure (B), green light-emitting AlGaInN-based light emitting diode structure (G) and red light-emitting AlGaInN-based light emitting diode structure (R) on an n-type GaN layer (11) and these AlGaInN-based light-emitting diode structures comprise an insulating film (12) having at least one opening (12a) provided on the n-type GaN layer, a truncated polygonal pyramid-shaped GaN layer (13) provided on the n-type GaN layer in the opening of the insulating film, a light emitting layer (14-16) provided along the upper surface and side surfaces of the GaN layer, a p-type GaN layer (17) provided to cover the light emitting layer, p-side electrodes (19) on the p-type GaN layer; and an n-side electrode (20) provided on the n-type GaN layer.

### TECHNICAL FIELD

The present invention relates to a micro light emitting diode chip, a micro light emitting diode chip transfer substrate, a micro light emitting diode display and XR (Cross Reality) glasses.

### BACKGROUND ART

Micro light emitting diode (LED) displays can achieve high brightness that far exceeds liquid crystal displays (LCDs) and organic EL displays (OLEDs), and are expected to be applied to XR glasses and large-screen TVs. However, since the manufacturing cost is extremely high, although commercialization has been achieved, the reality is that the high price of the product has prevented it from becoming widespread.

In order to realize low-cost micro LED displays, it is necessary to miniaturize the chip size to the order of a few μm. Therefore, it is necessary to introduce a technology that suppresses the decrease in luminous efficiency associated with miniaturization. The main reason for the decrease in luminous efficiency associated with miniaturization is related to the considerable number of defects that occur in the cross section when the chip is separated. Holes and electrons stay most in the active layer with the smallest band gap, and light is emitted by combining with each other there and emitting photons with energy according to the band gap. If there are many defects in the active layer, the proportion of holes and electrons that are captured by the defects and do not contribute to light emission increases. Holes and electrons (especially electrons) can move several μm on average before combining with the other carrier (hole) in the active layer. When the width of the active layer becomes the order of several μm with the miniaturization of the chip, the proportion of holes and electrons that are captured by defects on the sidewall of the active layer and disappear increases dramatically compared to the proportion of holes and electrons that combine. Therefore, as the chip size becomes smaller, such as several μm, the phenomenon of luminous efficiency also decreasing dramatically is observed. If the decrease in luminous efficiency of the LED can be suppressed even when the chip is miniaturized, the light emission area of the LED required to ensure brightness can be reduced, and material costs can be reduced.

With regard to the transfer of micro LED chips, there has been remarkable technological development in recent years, such as improvements in transfer speed and transfer yield. However, the reality is that problems such as the complexity of the process when transferring three types of chips that emit red (R), green (G), and blue (B) light separately to one pixel, the difficulty of measuring the characteristics and repairing of micro LED chips on the order of several μm, the difficulty of selecting defective chips due to the difficulty of chip measurement, and the low manufacturing yield due to the inclusion of a small number of defective micro LED chips have yet to be overcome.

Recently, a proposal has been announced to simplify the manufacturing process by growing GaN-based nanorods to form RGB three-color micro LED chips on the same substrate, and active research is being conducted (see, for example, Patent Literatures 1 and 2 and Non-Patent Literature 1). However, it is difficult to ensure the uniformity/reproducibility of the rod height and wavelength when growing GaN-based nanorods, and there are issues with stable production.

Furthermore, as a result of vigorous research by various research institutes, the efficiency of InGaN-based red LEDs grown on flat C-plane GaN has recently improved, and it is expected that full-color displays will be realized using only GaN-based LEDs without wavelength conversion (for example, see Non-Patent Literature 2).

However, despite rising expectations, no technology has emerged that can solve all of the above subjects at once, such as improving manufacturing yields, and the reality is that low prices for micro LED displays have not yet been achieved. For this reason, there is a need for technology that simultaneously achieves high manufacturing yields, simplifies the manufacturing process by integrating RGB, and provides measures against efficiency reduction due to sidewall damage.

### PRIOR ART LITERATURE

### Patent Literature

[PATENT LITERATURE 1] U.S. Pat. No. 5,547,076
[PATENT LITERATURE 2] U.S. Pat. No. 5,687,731

### Non-Patent Literature

[NON-PATENT LITERATURE 1] [Searched on Jun. 9, 2023], The Internet <URL: https://shingi.jst.go.jp/pdf/2018/2018_kisoken21.pdf [symbol]
[NON-PATENT LITERATURE 2] [Searched on Jun. 9, 2023], The Internet <URL: https://www.wavefront.co.jp/CAE/MOVPE-database/exp5.html

[symbol]

### SUMMARY OF INVENTION

### Subjects to be Solved by Invention

Therefore, the subject to be solved by the invention is to provide a micro light emitting diode chip that can emit RGB light with a single chip and obtain high luminous efficiency even when miniaturized, a micro light emitting diode chip transfer substrate capable of transferring a large number of micro light emitting diode chips easily, a high performance micro light emitting diode display using the micro light emitting diode chips and high performance XR glasses using the micro light emitting diode display.

### Means to Solve the Subjects

In order to solve the subject, according to the invention, there is provided a micro light emitting diode chip, comprising:
at least one blue light-emitting AlGaInN-based light emitting diode structure, at least one green light-emitting AlGaInN-based light emitting diode structure and at least one red light-emitting AlGaInN-based light emitting diode structure on an n-type GaN layer,
the blue light-emitting AlGaInN-based light emitting diode structure, the green light-emitting AlGaInN-based light emitting diode structure and the red light-emitting AlGaInN-based light emitting diode structure comprising:
an insulating film having at least one opening provided on the n-type GaN layer,
a truncated polygonal pyramid-shaped GaN layer provided on the n-type GaN layer in the opening of the insulating film,
a light emitting layer provided along the upper surface and side surfaces of the truncated polygonal pyramid-shaped GaN layer,
a p-type GaN layer provided to cover the light emitting layer,
one or a plurality of mutually separated p-side electrodes provided on the upper surface of the p-type GaN layer; and
at least one n-side electrode provided on the n-type GaN layer in a portion where the truncated polygonal pyramid-shaped GaN layer is not provided,

$${N}_{p} \times {N}_{b} \geq 2 , {N}_{p} \times {N}_{g} \geq 2 and {N}_{p} \times {N}_{r} \geq 2$$

being satisfied if the respective numbers of the blue light-emitting AlGaInN-based light emitting diode structures, the green light-emitting AlGaInN-based light emitting diode structures and the red light-emitting AlGaInN-based light emitting diode structures included in the entire micro light emitting diode chip are denoted as N_{b}, N_{g} and Nᵣ and the numbers of the p-side electrodes provided on the upper surface of the p-type GaN layer of each of the blue light-emitting AlGaInN-based light emitting diode structure, the green light-emitting AlGaInN-based light emitting diode structure and the red light-emitting AlGaInN-based light emitting diode structure is denoted as Nₚ.

The shape of the truncated polygonal pyramid-shaped GaN layer may be various shapes and is not particularly limited. The truncated polygonal pyramid-shaped GaN layer has, for example, a truncated hexagonal pyramid shape, a truncated hexagonal pyramid shape elongated in one direction, a truncated octagonal pyramid shape, and the like. This GaN layer may be undoped or n-type.

The shape of the opening of the insulating film is selected as necessary, and may be a polygon similar to or like the truncated polygonal pyramid-shaped GaN layer, or may be a shape other than a polygon, such as a circle. The arrangement of the openings of the insulating film is also selected as necessary. The insulating film is selected as necessary, and for example, an oxide film (SiO₂ film, and the like), a nitride film (Si₃N₄ film, and the like), an oxynitride film (SiON film, and the like), a titanium oxide film (TiO₂ film, and the like), and the like are used. Preferably, a part of the n-type GaN layer is formed by lateral growth, and the opening of the insulating film is formed on the n-type GaN layer in the part formed by the lateral growth. In this way, the threading dislocation density of the truncated polygonal pyramid-shaped GaN layer provided on the n-type GaN layer in the opening of the insulating film can be significantly reduced, and thereby the decrease in luminous efficiency due to non-radiative recombination in the threading dislocation part propagating from the truncated polygonal pyramid-shaped GaN layer to the light emitting layer and the leakage current due to the threading dislocation can be suppressed.

For example, the thickness of the p-type GaN layer above the upper surface of the truncated polygonal pyramid-shaped GaN layer may be selected to be smaller than the thickness of the p-type GaN layer above the side surface of the truncated polygonal pyramid-shaped GaN layer (thickness measured along a direction perpendicular to the upper surface of the truncated polygonal pyramid-shaped GaN layer) so that light is emitted mainly from the light emitting layer on the upper surface of the truncated polygonal pyramid-shaped GaN layer, or conversely, the thickness of the p-type GaN layer above the side surface of the truncated polygonal pyramid-shaped GaN layer may be selected to be smaller than the thickness of the p-type GaN layer above the upper surface of the truncated polygonal pyramid-shaped GaN layer so that light is emitted mainly from the light emitting layer on the side surface of the truncated polygonal pyramid-shaped GaN layer.

The p-side electrode may be at least partially transparent, and light from the light emitting layer may be extracted to the outside through this transparent portion, or may be made of a material containing a highly reflective metal layer such as Ag, and light from the light emitting layer may be extracted to the outside mainly from the n-side (for example, in a flip-chip mounting in which the p-side electrode (p-type layer) is on the mounting substrate side). The n-side electrode is provided on the n-type GaN layer in a portion where the truncated polygonal pyramid-shaped GaN layer is not provided, and is typically provided so as to contact the n-type GaN layer through an opening provided in the insulating film provided on the n-type GaN layer.

The blue light-emitting AlGaInN-based light emitting diode structure, the green light-emitting AlGaInN-based light emitting diode structure, and the red light-emitting AlGaInN-based light emitting diode structure typically have an InGaN-based light emitting layer, and by controlling the growth conditions of the light emitting layer, any of blue light emission (e.g., wavelength 440 nm˜470 nm), green light emission (e.g., wavelength 515 nm˜545 nm), and red light emission (e.g., wavelength 605 nm˜655 nm) is possible.

The chip size of the micro light emitting diode chip is selected as necessary, but is generally selected to be 20 μm×20 μm or less, typically 10 μm×10 μm or less, most typically 5 μm×5 μm or less, and typically is 0.5 μm×0.5 μm or more. Further, the thickness of the micro light emitting diode chip is also selected as necessary, but is typically 1 μm or more and 6 μm or less. The micro light emitting diode chip is preferably obtained by performing crystal growth of semiconductor layers constituting a light emitting diode structure on a substrate and then separating the substrate from the semiconductor layers. The overall shape of the micro light emitting diode chip is selected as necessary and is typically square or rectangular, although it is not particularly limited. The side surfaces of the micro light emitting diode chip are formed so that a part of the light emitting layer provided along the upper surface and side surfaces of the truncated polygonal pyramid-shaped GaN layer on the upper surface of the GaN layer is not exposed to the side surfaces. By doing this, after crystal growth of the semiconductor layers constituting the light emitting diode structure on the substrate, when the semiconductor layers are separated by dry etching such as RIE and made into chips, even if defects exist in the side surface formed by this chip formation is, the defects have almost no effect on the light emission because it is located sufficiently far from the light emitting layer on the upper surface of the truncated polygonal pyramid-shaped GaN layer where light emission mainly occurs. When one micro light emitting diode chip has a plurality of truncated polygonal pyramid-shaped GaN layers, the side surfaces of the micro light emitting diode chip are formed so that a part of the light emitting layer provided along the upper surface and side surfaces of at least one truncated polygonal pyramid-shaped GaN layer on the upper surface of the GaN layer is not exposed to the side surfaces.

In this micro light emitting diode chip, the number N_{b} of blue light-emitting AlGaInN-based light emitting diode structures, the number N_{g} of greenlight-emitting AlGaInN-based light emitting diode structures, the number Nᵣ of red light-emitting AlGaInN-based light emitting diode structures, and the number Nₚ of p-side electrodes provided on the upper surface of the p-type GaN layer of each of the blue light-emitting AlGaInN-based light emitting diode structures, the green light-emitting AlGaInN-based light emitting diode structures and the red light-emitting AlGaInN-based light emitting diode structures may be selected in any manner as long as they satisfy Nₚ×N_{b}≥2, Nₚ×N_{g}≥2 and Nₚ×Nᵣ≥2, and may be, for example, Nₚ×N_{b}≥3, Nₚ×N_{g}≥3 and Nₚ×Nᵣ≥3. For example, when Nₚ=1, N_{b}≥2, N_{g}≥2 and Nᵣ≥2, so that N_{b}, N_{g} and Nᵣ can be set to 2, 3, or 4. When N_{b}=1, N_{g}=1 and Nᵣ=1, Nₚ≥2 can be set.

According to the invention, there is provided a micro light emitting diode chip transfer substrate, comprising:
chip regions which are arranged in a two-dimensional array on an n-type GaN layer provided on a substrate, each of the chip regions including at least one blue light-emitting AlGaInN-based light emitting diode structure, at least one green light-emitting AlGaInN-based light emitting diode structure and at least one red light-emitting AlGaInN-based light emitting diode structure,
the blue light-emitting AlGaInN-based light emitting diode structure, the green light-emitting AlGaInN-based light emitting diode structure and the red light-emitting AlGaInN-based light emitting diode structure comprising:
an insulating film having at least one opening provided on the n-type GaN layer,
a truncated polygonal pyramid-shaped GaN layer provided on the n-type GaN layer in the opening of the insulating film,
a light emitting layer provided along the upper surface and side surfaces of the truncated polygonal pyramid-shaped GaN layer,
a p-type GaN layer provided to cover the light emitting layer,
one or a plurality of mutually separated p-side electrodes provided on the upper surface of the p-type GaN layer; and
at least one n-side electrode provided on the n-type GaN layer in a portion where the truncated polygonal pyramid-shaped GaN layer is not provided,

$${N}_{p} \times {N}_{b} \geq 2 , {N}_{p} \times {N}_{g} \geq 2 and {N}_{p} \times {N}_{r} \geq 2$$

being satisfied if the respective numbers of the blue light-emitting AlGaInN-based light emitting diode structures, the green light-emitting AlGaInN-based light emitting diode structures and the red light-emitting AlGaInN-based light emitting diode structures included in the entire micro light emitting diode chip are denoted as N_{b}, N_{g} and Nᵣ and the numbers of the p-side electrodes provided on the upper surface of the p-type GaN layer of each of the blue light-emitting AlGaInN-based light emitting diode structure, the green light-emitting AlGaInN-based light emitting diode structure and the red light-emitting AlGaInN-based light emitting diode structure is denoted as Nₚ,
the chip region being defined by a separation groove that separates the n-type GaN layer.

The substrate is not particularly limited as long as it allows the growth of AlGaInN-based semiconductor (especially C-plane growth), and examples thereof include a sapphire substrate, a Si substrate, and the like. In the invention of the micro light emitting diode chip transfer substrate, the matters described in relation to the invention of the micro light emitting diode chip described above are valid, unless otherwise stated and inconsistent with the nature of the invention.

According to the invention, there is provided a micro light emitting diode display, comprising:
a display section in which a plurality of micro light emitting diode chips are mounted in a two-dimensional array,
a drive circuit section in which a plurality of drive circuits which can be independently controlled and driven are provided in a two-dimensional array; and
a wiring circuit which wires the display section and the drive circuit section,
the micro light emitting diode chip being a micro light emitting diode chip comprising:
at least one blue light-emitting AlGaInN-based light emitting diode structure, at least one green light-emitting AlGaInN-based light emitting diode structure and at least one red light-emitting AlGaInN-based light emitting diode structure on an n-type GaN layer,
the blue light-emitting AlGaInN-based light emitting diode structure, the green light-emitting AlGaInN-based light emitting diode structure and the red light-emitting AlGaInN-based light emitting diode structure comprising:
an insulating film having at least one opening provided on the n-type GaN layer,
a truncated polygonal pyramid-shaped GaN layer provided on the n-type GaN layer in the opening of the insulating film,
a light emitting layer provided along the upper surface and side surfaces of the truncated polygonal pyramid-shaped GaN layer,
a p-type GaN layer provided to cover the light emitting layer,
one or a plurality of mutually separated p-side electrodes provided on the upper surface of the p-type GaN layer; and
at least one n-side electrode provided on the n-type GaN layer in a portion where the truncated polygonal pyramid-shaped GaN layer is not provided,

$${N}_{p} \times {N}_{b} \geq 2 , {N}_{p} \times {N}_{g} \geq 2 and {N}_{p} \times {N}_{r} \geq 2$$

being satisfied if the respective numbers of the blue light-emitting AlGaInN-based light emitting diode structures, the green light-emitting AlGaInN-based light emitting diode structures and the red light-emitting AlGaInN-based light emitting diode structures included in the entire micro light emitting diode chip are denoted as N_{b}, N_{g} and Nᵣ and the numbers of the p-side electrodes provided on the upper surface of the p-type GaN layer of each of the blue light-emitting AlGaInN-based light emitting diode structure, the green light-emitting AlGaInN-based light emitting diode structure and the red light-emitting AlGaInN-based light emitting diode structure is denoted as Nₚ.

This micro light emitting diode display can be used as a color display because the micro light emitting diode chips can emit light in three colors: red, green, and blue (RGB). This micro light emitting diode display may be driven by a passive matrix drive method, an active matrix drive method, a pulse width modulation (PWM) drive method, and the like. In a PWM drive type color display, for example, micro light emitting diode chips may be transferred onto an IC substrate with a built-in PWM drive circuit. In this micro light emitting diode display, in one typical example, a plurality of p-side electrodes are provided separately from each other for each of the blue light-emitting AlGaInN-based light emitting diode structure, the green light-emitting AlGaInN-based light emitting diode structure and the red light-emitting AlGaInN-based light emitting diode structure, and at least one n-side electrode is provided. In each micro light emitting diode chip, each of a plurality of branch wirings branched from a first trunk wiring which is connected to the drive circuit of the drive circuit section via the wiring of the wiring circuit and each p-side electrode are electrically connected to each other, and a second trunk wiring which is connected to the drive circuit of the drive circuit section via the wiring of the wiring circuit and the n-side electrodes are electrically connected to each other.

In the invention of the micro light emitting diode display, the matters explained in connection with the invention of the micro light emitting diode chip described above hold true unless otherwise contrary to the nature thereof.

According to the invention, there is provided XR glasses comprising:
a display,
the display comprising:
a display section in which a plurality of micro light-emitting diode chips are mounted in a two-dimensional array,
   a drive circuit board on which a plurality of drive circuits which can be independently controlled and driven are provided in a two-dimensional array; and
a flexible printed circuit wiring the display section and the drive circuit board,
the micro light emitting diode chip being a micro light emitting diode chip, comprising:
at least one blue light-emitting AlGaInN-based light emitting diode structure, at least one green light-emitting AlGaInN-based light emitting diode structure and at least one red light-emitting AlGaInN-based light emitting diode structure on an n-type GaN layer,
the blue light-emitting AlGaInN-based light emitting diode structure, the green light-emitting AlGaInN-based light emitting diode structure and the red light-emitting AlGaInN-based light emitting diode structure comprising:
an insulating film having at least one opening provided on the n-type GaN layer,
a truncated polygonal pyramid-shaped GaN layer provided on the n-type GaN layer in the opening of the insulating film,
a light emitting layer provided along the upper surface and side surfaces of the truncated polygonal pyramid-shaped GaN layer,
a p-type GaN layer provided to cover the light emitting layer,
one or a plurality of mutually separated p-side electrodes provided on the upper surface of the p-type GaN layer; and
at least one n-side electrode provided on the n-type GaN layer in a portion where the truncated polygonal pyramid-shaped GaN layer is not provided,

$${N}_{p} \times {N}_{b} \geq 2 , {N}_{p} \times {N}_{g} \geq 2 and {N}_{p} \times {N}_{r} \geq 2$$

being satisfied if the respective numbers of the blue light-emitting AlGaInN-based light emitting diode structures, the green light-emitting AlGaInN-based light emitting diode structures and the red light-emitting AlGaInN-based light emitting diode structures included in the entire micro light emitting diode chip are denoted as N_{b}, N_{g} and Nᵣ and the numbers of the p-side electrodes provided on the upper surface of the p-type GaN layer of each of the blue light-emitting AlGaInN-based light emitting diode structure, the green light-emitting AlGaInN-based light emitting diode structure and the red light-emitting AlGaInN-based light emitting diode structure is denoted as Nₚ.

In the XR glasses, the locations for mounting the display section, the driving circuit board and the flexible printed circuit are selected as necessary and are not particularly limited. For example, the display section is mounted on the inner surface of the windshield, the driving circuit board is mounted on the ear hook of the frame, and the flexible printed circuit is mounted on the frame. The XR glasses (Cross Reality) are general terms for glasses that use technologies such as VR (Virtual Reality), AR (Augmented Reality), MR (Mixed Reality), SR (Substitutional Reality), and the like, a combination of these technologies (for example, a technology that combines VR and AR), and an intermediate technology between these technologies (for example, a technology that is positioned between AR and MR), and is an image display device that creates a space that provides a simulated experience by fusing the real and virtual worlds. VR is a technology that allows you to experience the virtual world as if it were the real world, AR is a technology that projects the virtual world onto the real space, MR is a technology that fuses the real space and the virtual space, and SR is a technology that overlays past images onto the real space, making it appear as if a past event is happening right in front of you.

In the XR glasses, in one typical example, a plurality of p-side electrodes are provided separately from each other for each of the blue light-emitting AlGaInN-based light emitting diode structure, the green light-emitting AlGaInN-based light emitting diode structure and the red light-emitting AlGaInN-based light emitting diode structure, and at least one n-side electrode is provided. In each micro light emitting diode chip, each of a plurality of branch wirings branched from a first trunk wiring which is connected to the drive circuit of the drive circuit board via the flexible printed circuit and p-side electrodes are electrically connected to each other. A second trunk line which is connected to the drive circuit of the drive circuit board via the flexible printed circuit and the n-side electrode are electrically connected to each other. In the invention of the XR glasses, except for the above, the matters explained in connection with the invention of the micro light emitting diode chip described above hold true unless it is contrary to the nature thereof.

### Effect of the Invention

According to the invention, since the micro light emitting diode chip has a blue light-emitting AlGaInN-based light emitting diode structure, a green light-emitting AlGaInN-based light emitting diode structure and a red light-emitting AlGaInN-based light emitting diode structure on an n-type GaN layer, one chip can emit blue, green, and red light. In addition, each light emitting diode structure has a light emitting layer along the upper surface and side surfaces of the truncated polygonal pyramid-shaped GaN layer. Therefore, even if there are defects caused by dry etching, and the like, they have almost no effect on the light emission, so even with miniaturization, high luminous efficiency can be obtained, and the simple structure makes it easy to manufacture.

A high-performance micro LED display can be realized using this high-performance micro light emitting diode chip, and a high-performance XR glasses can be realized using this micro LED display. In addition, by using a micro light emitting diode chip transfer substrate which has a blue light-emitting AlGaInN-based light emitting diode structure, a green light-emitting AlGaInN-based light emitting diode structure and a red light-emitting AlGaInN-based light emitting diode structure on an n-type GaN layer in each chip region, it is possible to transfer, for example, millions to tens of millions of micro light emitting diode chips onto a mounting board at once, and it is possible to easily manufacture micro-LED displays with large areas or high integration density.

Further, according to the present invention, one chip can emit blue, green and red light, and has a plurality of electrodes or light emitting diode structures for each emission wavelength, and these can be independently controlled. Therefore, even if millions to tens of millions of micro light emitting diode chips are transferred and assembled at once, omitting the inspection of each individual chip (100% inspection), it is possible to cut out defective parts due to disconnection of wiring. Since the pixel can be repaired using the same method, a high manufacturing yield of micro LED displays can be ensured.

### BRIEF DESCRIPTION OF THE DRAWINGS

FIG. 1A A perspective view showing a micro LED chip according to a first embodiment of the invention.

FIG. 1B A cross-sectional view showing the micro LED chip according to the first embodiment of the invention.

FIG. 1C A cross-sectional view showing the micro LED chip according to the first embodiment of the invention.

FIG. 2A A plan view for explaining an example of a method of manufacturing the micro LED chip according to the first embodiment of the invention.

FIG. 2B A cross-sectional view for explaining the example of a method of manufacturing the micro LED chip according to the first embodiment of the invention.

FIG. 3 A cross-sectional view for explaining the example of a method of manufacturing the micro LED chip according to the first embodiment of the invention.

FIG. 4 A cross-sectional view for explaining the example of a method of manufacturing the micro LED chip according to the first embodiment of the invention.

FIG. 5 A cross-sectional view for explaining the example of a method of manufacturing the micro LED chip according to the first embodiment of the invention.

FIG. 6 A cross-sectional view for explaining the example of a method of manufacturing the micro LED chip according to the first embodiment of the invention.

FIG. 7 A cross-sectional view for explaining the example of a method of manufacturing the micro LED chip according to the first embodiment of the invention.

FIG. 8 A cross-sectional view for explaining the example of a method of manufacturing the micro LED chip according to the first embodiment of the invention.

FIG. 9 A cross-sectional view for explaining the example of a method of manufacturing the micro LED chip according to the first embodiment of the invention.

FIG. 10A A cross-sectional view for explaining the example of a method of manufacturing the micro LED chip according to the first embodiment of the invention.

FIG. 10B A cross-sectional view for explaining the example of a method of manufacturing the micro LED chip according to the first embodiment of the invention.

FIG. 11A A cross-sectional view for explaining the example of a method of manufacturing the micro LED chip according to the first embodiment of the invention.

FIG. 11B A cross-sectional view for explaining the example of a method of manufacturing the micro LED chip according to the first embodiment of the invention.

FIG. 12 A cross-sectional view for explaining the example of a method of manufacturing the micro LED chip according to the first embodiment of the invention.

FIG. 13 A cross-sectional view for explaining the example of a method of manufacturing the micro LED chip according to the first embodiment of the invention.

FIG. 14 A cross-sectional view for explaining the example of a method of manufacturing the micro LED chip according to the first embodiment of the invention.

FIG. 15 A cross-sectional view showing a micro LED chip transfer substrate according to a second embodiment of the invention.

FIG. 16A A cross-sectional view for explaining a method of manufacturing the micro LED chip transfer substrate according to the second embodiment of the invention.

FIG. 16B A cross-sectional view for explaining a method of manufacturing the micro LED chip transfer substrate according to the second embodiment of the invention.

FIG. 17A A perspective view showing a micro LED chip according to a third embodiment of the invention.

FIG. 17B A cross-sectional view showing the micro LED chip according to the third embodiment of the invention.

FIG. 17C A cross-sectional view showing the micro LED chip according to the third embodiment of the invention.

FIG. 18A A plan view for explaining a method of manufacturing the micro LED chip according to the third embodiment of the invention.

FIG. 18B A cross-sectional view for explaining the method of manufacturing the micro LED chip according to the third embodiment of the invention.

FIG. 19A A plan view for explaining the method of manufacturing the micro LED chip according to the third embodiment of the invention.

FIG. 19B A cross-sectional view for explaining the method of manufacturing the micro LED chip according to the third embodiment of the invention.

FIG. 20 A cross-sectional view showing a micro LED chip transfer substrate according to a fourth embodiment of the invention.

FIG. 21 A perspective view showing XR glasses according to a fifth embodiment of the invention.

FIG. 22 A plan view showing a display section 300, a flexible printed circuit 400 and a print wired board 500 of the XR glasses according to the fifth embodiment of the invention.

FIG. 23A A plan view showing the display section 300 of the XR glasses according to the fifth embodiment of the invention.

FIG. 23B A cross-sectional view showing the display section 300 of the XR glasses according to the fifth embodiment of the invention.

FIG. 23C A cross-sectional view showing the display section 300 of the XR glasses according to the fifth embodiment of the invention.

FIG. 24 A perspective view showing XR glasses according to a sixth embodiment of the invention.

FIG. 25 A developed view of a light engine 600 of the XR glasses according to the sixth embodiment of the present invention.

FIG. 26A A plan view showing a LED array section 610 of the XR glasses according to the sixth embodiment of the invention.

FIG. 26B A cross-sectional view showing the LED array section 610 of the XR glasses according to the sixth embodiment of the invention.

FIG. 26C A cross-sectional view showing the LED array section 610 of the XR glasses according to the sixth embodiment of the invention.

FIG. 27 A cross-sectional view showing the configuration of the light engine 600 of XR glasses according to a seventh embodiment of the present invention.

### MODES FOR CARRYING OUT THE INVENTION

Modes for carrying out the invention (hereinafter referred as embodiments) will now be explained below.

### The First Embodiment

### [Micro LED Chip]

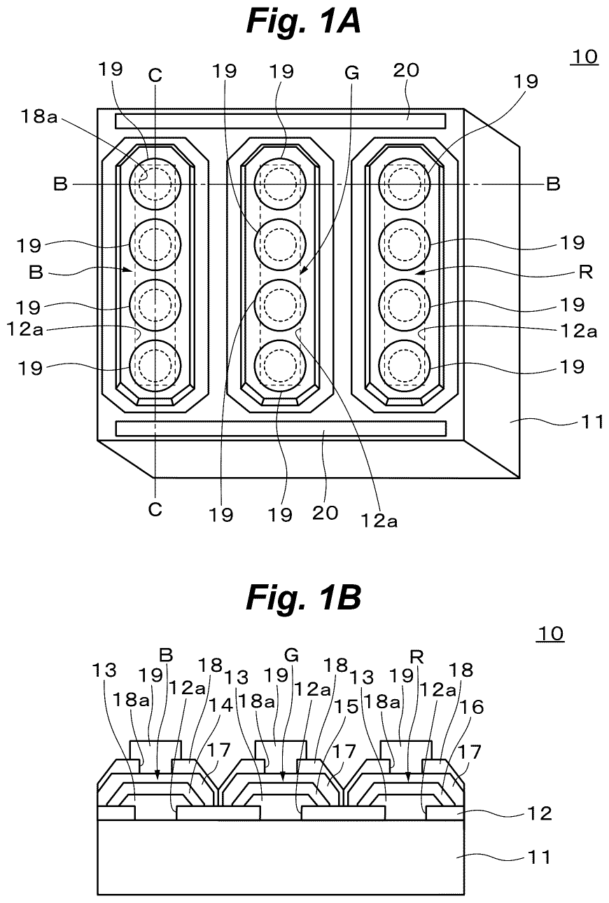

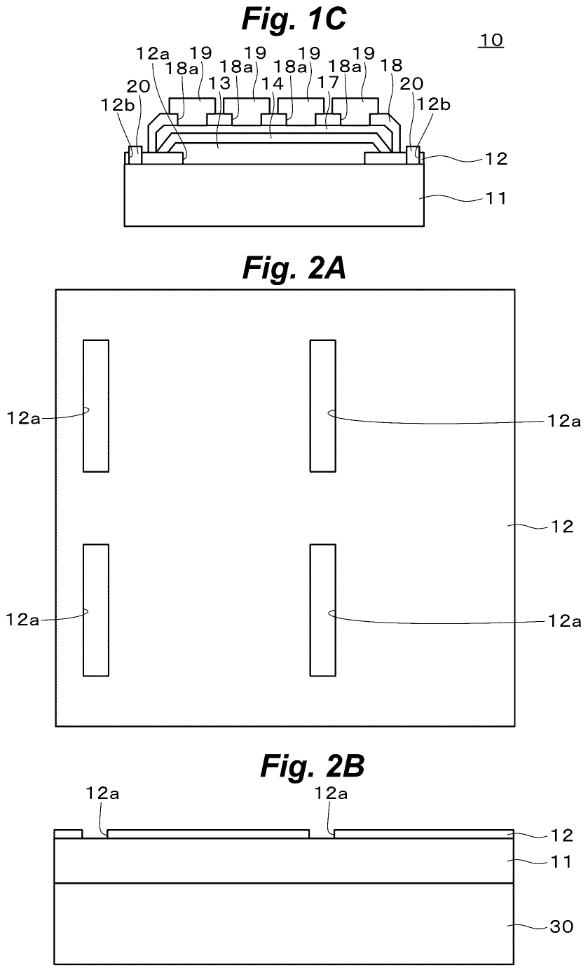

FIG. 1A, FIG. 1B and FIG. 1C show a micro LED chip 10 according to the first embodiment. Here, FIG. 1A is a perspective view, FIG. 1B is a cross-sectional view along the B-B line in FIG. 1A and FIG. 1C is a cross-sectional view along the C-C line in FIG. 1A. As shown in FIG. 1A, FIG. 1B and FIG. 1C, the micro LED chip 10 has a square or rectangular shape and includes a blue light-emitting AlGaInN-based LED structure B, a green light-emitting AlGaInN-based LED structure G and a red light-emitting AlGaInN-based LED structure R. In the micro LED chip 10, an insulating film 12 is provided on an n-type GaN layer 11. As already mentioned, the insulating film 12 is a SiO₂ film, and the like. The thickness of the insulating film 12 is selected as necessary, and is, for example, 10 to 30 nm. The n-type GaN layer 11 is generally grown on a sapphire substrate, a Si substrate, and the like via a low-temperature buffer layer, and usually has a large number of threading dislocations (approximately 10⁸ to 10¹⁰/cm²). Threading dislocations can lead to reduced luminous efficiency and electrical leakage. Therefore, the n-type GaN layer 11 is preferably laterally grown by a conventionally known ELO (Epitaxial Lateral Overgrowth) method, and partially has a low-threading-dislocation-density region (not shown). The region of the n-type GaN layer 11 corresponding to the seed (seed crystal) used for lateral growth and the region (meeting portion) where layers grown laterally from adjacent seeds meet are high dislocation density regions (approximately 10⁸ to 10¹⁰/cm²), while the laterally grown region between these regions is a low dislocation density region (approximately 10⁶ to 10⁷/cm²).

The insulating film 12 has three elongated rectangular openings 12a having the same planar shape, which are parallel to each other and equally spaced apart, on the low dislocation density region of the n-type GaN layer 11. The size of the openings 12a is selected as necessary, and is, for example, (100 to 2000 nm)×(1 to 10 μm). On the n-type GaN layer 11 at the portion of each opening 12a, an island-shaped GaN layer 13, which is elongated in the longitudinal direction of the opening 12a, is provided so as to extend on the insulating film 12 while being separated from each other. In this case, the GaN layer 13 has a truncated octagonal pyramid shape extending in the longitudinal direction of the opening 12a. The GaN layer 13 may be undoped or n-type. In FIG. 1A and FIG. 1B, a light emitting layer 14 for emitting blue light is provided in an island shape along the upper surface and side surfaces (slope surfaces) of the GaN layer 13 in the leftmost opening 12a, a light emitting layer 15 for emitting green light is provided in an island shape along the upper surface and side surfaces (slope surfaces) of the GaN layer 13 in the central opening 12a, and a light emitting layer 16 for emitting red light is provided in an island shape along the upper surface and side surfaces (slope surfaces) of the GaN layer 13 in the rightmost opening 12a. P-type GaN layers 17 are provided separately from each other so as to cover the light emitting layers 14, 15, 16, respectively. By appropriately selecting conditions such as temperature, growth rate, pressure, and the like during crystal growth of the p-type GaN layer 17, the growth of the p-type GaN layer 17 in the lateral (horizontal) direction relative to the longitudinal (vertical) direction is promoted, and a part or all of the p-type GaN layer 17 above the upper surface of the GaN layer 13 and above the side surfaces (slope surfaces) of the GaN layer 13 is flattened. Therefore, the thickness of the p-type GaN layer 17 above the upper surface of the GaN layer 13 is smaller than the thickness of the p-type GaN layer 17 above the side surfaces (slope surfaces) of the GaN layer 13. Note that a p-type AlGaN layer or the like is often inserted between the light emitting layers 14, 15, 16 and the p-type GaN layer 17, but illustration and description thereof are omitted.

The light emitting layers 14, 15, 16 have, for example, an InₓGa₁₋ₓN/In_{y}Ga_{1-y}N multiple quantum well (MQW) structure (x<y, 0≤x<1, 0≤y<1) in which InₓGa₁₋ₓN layers as barrier layers and In_{y}Ga_{1-y}N layers as well layers are alternately stacked. The In composition ratios x and y of the InₓGa₁₋ₓN/In_{y}Ga_{1-y}N MQW structure constituting the light emitting layer 14 are selected according to the emission wavelength of blue light, the In composition ratios x, y of the InₓGa₁₋ₓN/In_{y}Ga_{1-y}N MQW structure constituting the light emitting layer 15 are selected according to the emission wavelength of green light, and the In composition ratios x, y of the InₓGa₁₋ₓN/In_{y}Ga_{1-y}N MQW structure constituting the light emitting layer 16 are selected according to the emission wavelength of red light. These In composition ratios x, y also change depending on the growth conditions of the InₓGa₁₋ₓN layer and the In_{y}Ga_{1-y}N layer, and the like. The In composition of the light emitting layers 14, 15, 16 formed in a truncated octagonal pyramid shape following the truncated octagonal pyramid shape of the GaN layer 13 is larger in the portion on the upper surface of the GaN layer 13 than in the portion on the side surfaces of the GaN layer 13. This is because, compared to InGaN grown on the C-plane, which is a polar plane, In composition tends to be lower at the same temperature in InGaN grown on nonpolar and semipolar planes. Therefore, the band gap of the portions of the light emitting layers 14, 15, 16 on the side surfaces of the GaN layer 13 is larger than the band gap of the portions on the upper surface of the GaN layer 13.

The n-type GaN layer 11, the GaN layer 13, the light emitting layer 14 and the p-type GaN layer 17 in the leftmost opening 12a form the AlGaInN-based LED structure B that emits blue light, the n-type GaN layer 11, the GaN layer 13, the light emitting layer 15 and the p-type GaN layer 17 in the central opening 12a form the AlGaInN-based LED structure G that emits green light, and the n-type GaN layer 11, the GaN layer 13, the light emitting layer 16 and the p-type GaN layer 17 in the rightmost opening 12a form the AlGaInN-based LED structure R that emits red light.

An insulating film 18 is provided so as to cover each p-type GaN layer 17. In the insulating film 18, a plurality of (four in this example) circular openings 18a are provided in a row at equal intervals on the center line in the longitudinal direction of each p-type GaN layer 17. The diameter of the openings 18a is selected as necessary, but is typically about the width (100 to 2000 nm) of the opening 12a. A plurality of (four in this example) p-side electrodes 19 are provided in a row on the p-type GaN layer 17, separated from each other, at positions corresponding to each of the light emitting layers 14, 15, 16 on the center line in the longitudinal direction through each opening 18a. In this case, the number N_{b} of the blue light-emitting AlGaInN-based LED structures B, the number N_{g} of the green light-emitting AlGaInN-based LED structures G, and the number Nᵣ of the red light-emitting AlGaInN-based LED structures R are N_{b}=N_{g}=Nᵣ=1, so the number Nₚ of the p-side electrodes 19 is selected from Nₚ×N_{b}≥2, Nₚ×N_{g}≥2, and Nₚ×Nᵣ≥2 in a range that satisfies Nₚ≥2, but in FIG. 1A, FIG. 1B and FIG. 1C, Nₚ is selected as 4. The p-side electrode 19 is made of a multi-layered film such as an ITO/Ag/Ti/Au film. Here, Ag is used to increase the reflectance of light by the p-side electrode 19 when light is extracted from the n-type GaN layer 11 side of the micro LED chip 10. Here, the thicknesses of the ITO film, Ag film, Ti film and Au film constituting the p-side electrode 19 are, for example, 50 nm, 100 nm, 20 nm and 50 nm, respectively. A pair of elongated rectangular contact holes 12b are provided in a portion of the insulating film 12 away from the GaN layer 13 in a direction perpendicular to the extension direction of the GaN layer 13, parallel to the sides of the chip so as to sandwich the GaN layer 13, and two elongated rectangular n-side electrodes 20 are provided in contact with the n-type GaN layer 11 through the contact holes 12b. The n-side electrodes 20 are made of a multi-layered film such as Ti/Al/Ti/Ni/Au films.

The n-type GaN layer 11, the light emitting layers 14, 15, 16, and the p-type GaN layer 17 typically have a C-plane orientation. The resistivity of the n-type GaN layer 11 and the GaN layer 13 is, for example, about 0.01 Ωcm, but is not limited to this. The resistivity of the light emitting layers 14, 15, 16 is, for example, about 0.1 to 0.3 Ωcm, but is not limited thereto. The resistivity of the p-type GaN layer 17 is, for example, about 1 to 3 Ωcm, but is not limited thereto. The thickness of the n-type GaN layer 11 is, for example, 1 to 5 μm, the thickness of the GaN layer 13 is, for example, 100 to 1500 nm, the thickness of the light emitting layers 14, 15, 16 is, for example, 30 to 100 nm, and the thickness of the p-type GaN layer 17 in the portion above the upper surface of the GaN layer 13 is, for example, 100 to 200 nm, but is not limited thereto. The total thickness of the n-type GaN layer 11, the GaN layer 13, the light emitting layers 14, 15, 16, and the p-type GaN layer 17 is, for example, 1.2 to 6.8 μm, but is not limited thereto.

### [Operation of Micro LED Chip]

In this micro LED chip 10, blue light can be emitted by applying a forward bias between the p-side electrode 19 and the n-side electrode 20 in the blue light-emitting AlGaInN-based LED structure B, green light can be emitted by applying a forward bias between the p-side electrode 19 and the n-side electrode 20 in the green light-emitting AlGaInN-based LED structure G, and red light can be emitted by applying a forward bias between the p-side electrode 19 and the n-side electrode 20 in the red light-emitting AlGaInN based-LED structure R. In this case, the n-type GaN layer 11 and the p-type GaN layer 17 are separated by the insulating film 12 in the portion other than the opening 12a, so that the occurrence of leakage current during operation can be effectively suppressed. Furthermore, the thickness of the p-type GaN layer 17, which has a high resistivity, is smaller in the portion above the upper surface of the GaN layer 13 than in the portion above the side surfaces (slope surfaces) of the GaN layer 13. Therefore, the current flowing between the p-side electrode 19 and the n-side electrode 20 passes mainly through the p-type GaN layer 17 in the portion above the upper surface of the GaN layer 13, which has a lower resistance, and only a small amount of current passes through the p-type GaN layer 17 in the portion above the side surfaces of the GaN layer 13. In addition, the In composition ratios x, y of the MQW structure of the light emitting layers 14, 15, 16 are smaller in the portion above the side surfaces of the GaN layer 13 than in the portion above the upper surface of the GaN layer 13, so that the band gap of the light emitting layers 14, 15, 16 is smaller in the portion above the upper surface of the GaN layer 13 than in the portion above the side surfaces of the GaN layer 13, but carriers (electrons, holes) tend to gather in the light emitting layers 14, 15, 16 in the portion above the upper surface of the GaN layer 13, which has a smaller band gap. Then, a current flows between the p-side electrode 19 and the n-side electrode 20 in this way, and light is emitted mainly from the light emitting layers 14, 15, 16 in the portion above the upper surface of the GaN layer 13, and this light is extracted to the outside through the n-type GaN layer 11.

### [Manufacturing Method of Micro LED Chip]

An example of a method for manufacturing a micro LED chip will be described.

First, as shown in FIG. 2A and FIG. 2B, the n-type GaN layer 11 is grown on a C-plane oriented sapphire substrate 30 by, for example, a metal organic chemical vapor deposition (MOCVD) method. Here, FIG. 2A is a plan view, and FIG. 2B is a cross-sectional view. The growth of the n-type GaN layer 11 is performed, for example, as follows, but is not limited thereto. That is, first, a GaN layer is epitaxially grown on the sapphire substrate 30 by the MOCVD method, and then a seed (not shown) is formed by patterning the GaN layer by a conventionally known method. Next, the n-type GaN layer 11 is grown by lateral growth from the seed using the ELO method based on the conventionally known MOCVD method. At this time, the growth is stopped when the island-shaped n-type GaN layer 11 collides with the adjacent island-shaped n-type GaN layer 11. In some cases, adjacent island-shaped n-type GaN layers 11 may continue to grow even after colliding with each other, or it is also possible to stop growth at a certain point before the n-type GaN layers 11 collide with each other by appropriately designing the seed position and lateral growth distance. Next, the insulating film 12 such as a SiO₂ film is formed on the n-type GaN layer 11 by a chemical vapor deposition (CVD) method, a sputtering method, a vacuum evaporation method, and the like, and then the insulating film 12 is patterned by a conventionally known method. By doing so, an elongated rectangular opening 12a is formed in a portion where the blue light-emitting AlGaInN-based LED structure B is to be formed. The opening 12a is formed in a laterally grown region of the n-type GaN layer 11 where the threading dislocation density is low.

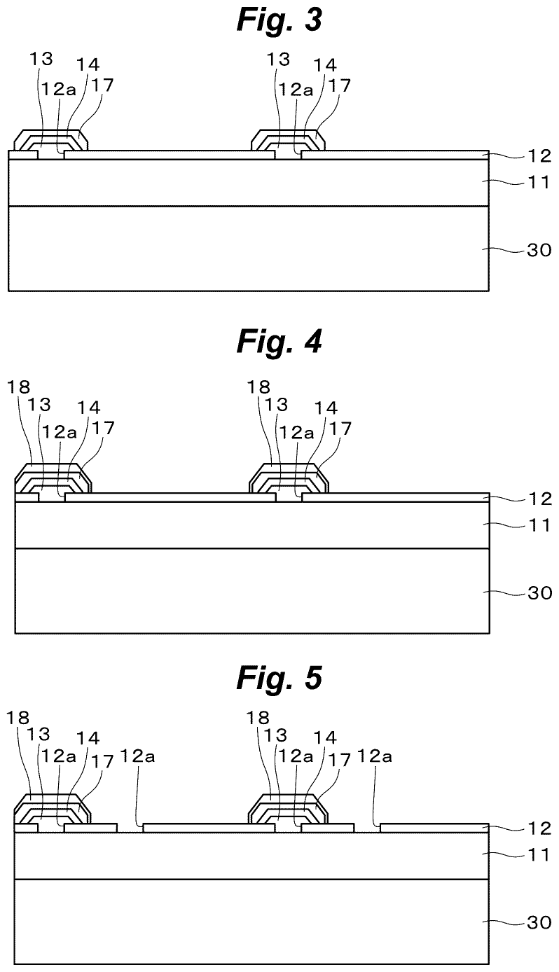

Next, as shown in FIG. 3, the GaN layer 13 is grown in the shape of a truncated octagonal pyramid island in each opening 12a by the ELO method. In this case, first, GaN selectively grows on the surface of the n-type GaN layer 11 exposed in the opening 12a of the insulating film 12, and then laterally grows on the insulating film 12, thereby forming the GaN layer 13 on the insulating film 12. Next, the light emitting layer 14 having the InₓGa₁₋ₓN/In_{y}Ga_{1-y}N MQW structure is epitaxially grown on the island-shaped GaN layer 13 grown in this manner. The blue light emitting layer 14 can be grown by a conventionally known growth method. Usually, the In composition of the InGaN layer grown on the upper surface (C-plane) of the GaN layer 13 is smaller than the In composition of the InGaN layer grown on the side surfaces (semipolar plane). Subsequently, the p-type GaN layer 17 is epitaxially grown to cover the light emitting layer 14. The thickness of the p-type GaN layer 17 in the portion above the upper surface of the GaN layer 13 is formed to be smaller than the thickness of the p-type GaN layer 17 in the portion above the side surfaces of the GaN layer 13 by adjusting growth conditions such as pressure and temperature. The growth of the GaN layer 13, the light emitting layer 14, and the p-type GaN layer 17 is performed continuously in an MOCVD furnace.

Next, as shown in FIG. 4, the insulating film 18 such as a SiO₂ film is formed by, for example, a vacuum evaporation method so as to cover the p-type GaN layer 17.

Next, as shown in FIG. 5, by patterning the insulating film 12 by a conventionally known method, the elongated rectangular opening 12a is formed in a portion where the green light-emitting AlGaInN-based LED structure G is to be formed.

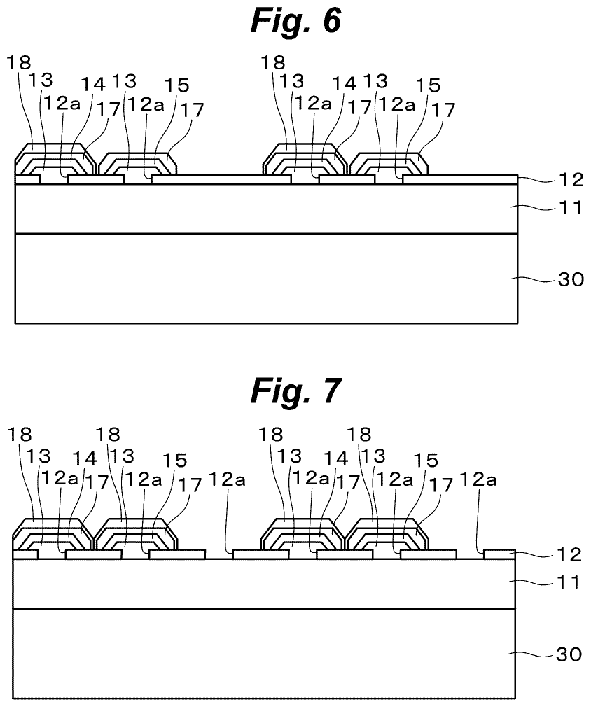

Next, as shown in FIG. 6, on the n-type GaN layer 11 exposed in the newly formed opening 12a, the GaN layer 13, the light emitting layer 15 having the InₓGa₁₋ₓN/In_{y}Ga_{1-y}N MQW structure and the p-type GaN layer 17 are sequentially grown. The green light emitting layer 15 can be grown by a conventionally known growth method.

Next, as shown in FIG. 7, the insulating film 18 such as a SiO₂ film is formed by, for example, a vacuum deposition method so as to cover the p-type GaN layer 17, and then the insulating film 12 is patterned by a conventionally known method to form the elongated rectangular opening 12a in a portion where the red light emitting AlGaInN-based LED structure R is to be formed.

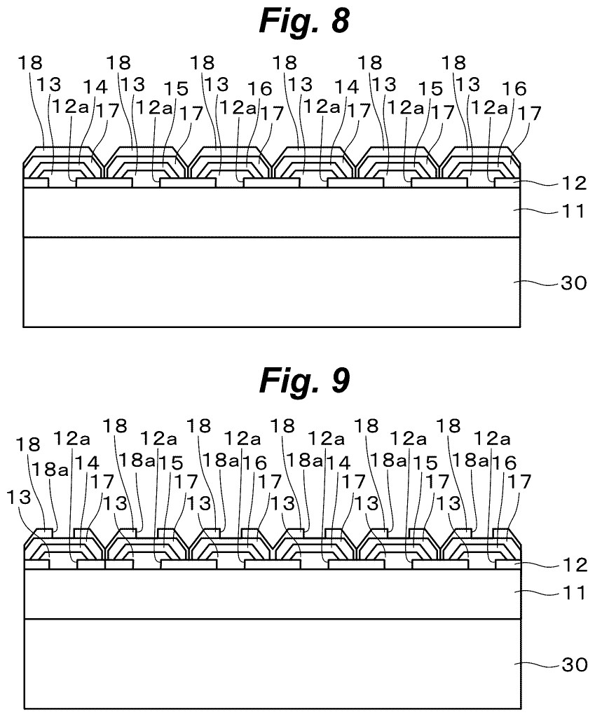

Next, as shown in FIG. 8, on the n-type GaN layer 11 exposed in the newly formed opening 12a, the GaN layer 13, the light emitting layer 16 having the InₓGa₁₋ₓN/In_{y}Ga_{1-y}N MQW structure and the p-type GaN layer 17 are successively grown in the same manner as in the portion for forming the blue light-emitting AlGaInN-based LED structure B. The red light-emitting light emitting layer 16 can be grown by a conventionally known growth method (for example, Non-Patent Literature 2). Subsequently, the insulating film 18 such as a SiO₂ film is formed by, for example, a vacuum evaporation method so as to cover the p-type GaN layer 17.

Next, as shown in FIG. 9, a circular contact hole 18a is formed in the insulating film 18 above each of the blue light-emitting AlGaInN-based LED structure B, the green light-emitting AlGaInN-based LED structure G and the red light-emitting AlGaInN-based LED structure R. The p-type GaN layer 17 is exposed inside the contact hole 18a.

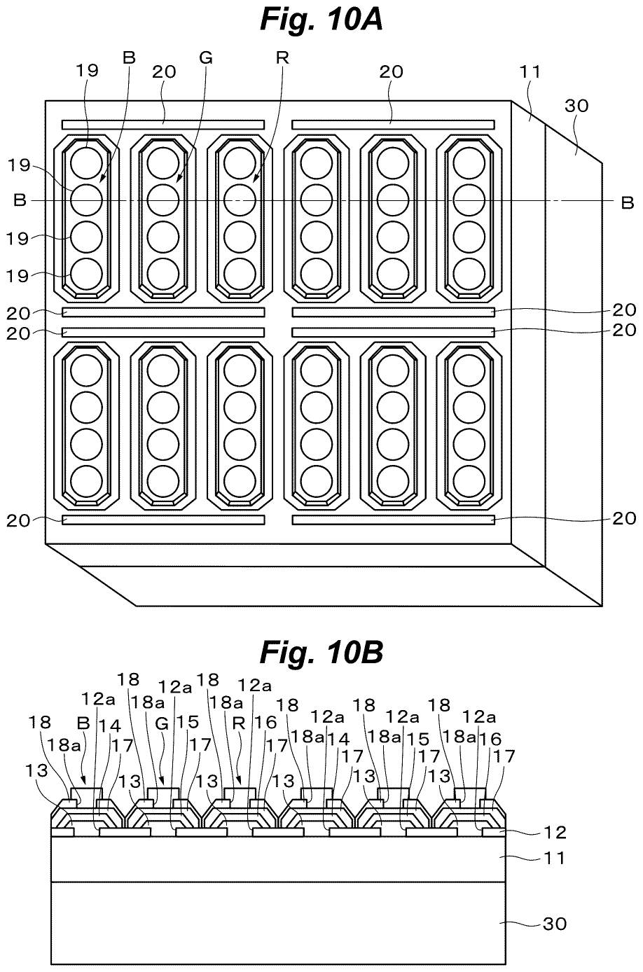

Next, as shown in FIG. 10A and FIG. 10B, the p-side electrode 19 is formed to contact the p-type GaN layer 17 through the contact hole 18a. Here, FIG. 10A is a plan view, and FIG. 10B is a cross-sectional view taken along the B-B line in FIG. 10A. For example, the p-side electrode 19 can be formed as follows. That is, after an ITO film, an Ag film, a Ti film, and an Au film are sequentially formed on the entire surface of the substrate by, for example, a sputtering method or a vacuum evaporation method, the ITO film, Ag film, Ti film, and Au film are patterned by etching, and the like. Next, by patterning the insulating film 12 by a conventionally known method, two elongated rectangular contact holes 12b (see FIG. 1C) for n-side electrodes are formed in parallel to each other so as to sandwich the entire blue light-emitting AlGaInN-based LED structure B, green light-emitting AlGaInN-based LED structure G, and red light-emitting AlGaInN-based LED structure R from both sides, and the n-type GaN layer 11 is exposed inside these contact holes 12b. Next, the elongated rectangular n-side electrode 20 is formed so as to contact the n-type GaN layer 11 through each contact hole 12b. There may be one or more n-side electrodes 20, and in the example shown in FIG. 10A and FIG. 10B, two are formed.

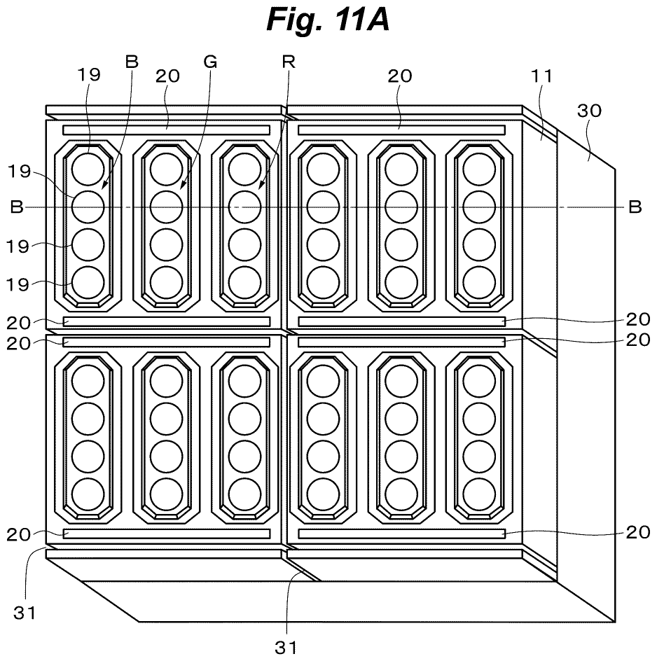

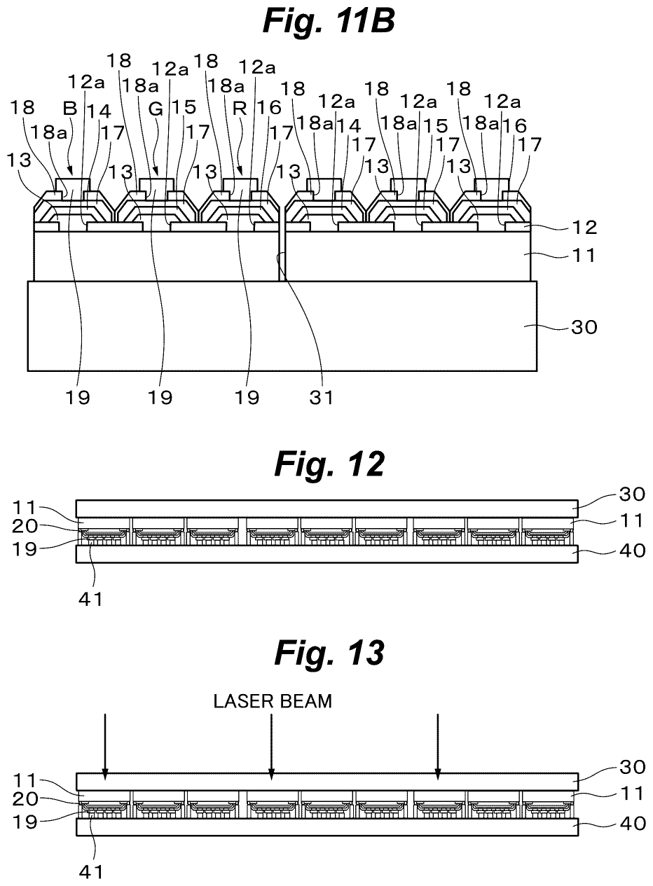

Next, as shown in FIG. 11A and FIG. 11B, an etching mask (not shown) for chip separation is formed, and then etching is carried out in a vertical direction to the sapphire substrate 30 by an RIE method using the etching mask until the sapphire substrate 30 is reached. In this way, separation grooves 31 are formed.

Next, as shown in FIG. 12, prepared is a secondary substrate 40 with solder layers 41 formed thereon in the arrangement pattern as the same as the arrangement pattern of the p-side electrodes 19 and the n-side electrodes 20 of the chip region selected from all the chip regions (including the case where all the chip regions are selected). And the secondary substrate 40 and the sapphire substrate 30 formed up to the separation groove 31 shown in FIG. 11A and FIG. 11B are overlapped so that the solder layers 41 of the secondary substrate 40 and the p-side electrodes 19 and the n-side electrodes 20 of the sapphire substrate 30 correspond to each other.

Next, as shown in FIG. 13, a laser beam is irradiated from the back side of the sapphire substrate 30 onto all or selected chip regions, causing peeling at the interface between the n-type GaN layer 11 in the chip region and the sapphire substrate 30 to separate the sapphire substrate 30 (laser lift-off), and at the same time, the solder layers 41 in the portion corresponding to the chip region is melted by conduction of heat generated in the blue light-emitting AlGaInN-based LED structure B, the green light-emitting AlGaInN-based LED structure G, and the red light-emitting AlGaInN-based LED structure R during the laser beam irradiation. After that, the solder layers 41 cool and solidify, and then the sapphire substrate 30 is separated from the secondary substrate 40. When the laser beam is irradiated only onto the selected chip region from the back side of the sapphire substrate 30, the laser beam is irradiated using a predetermined mask (not shown) in which only the portion corresponding to the selected chip region is opened. Since the sapphire substrate 30 is transparent to visible light, it may be left as it is without peeling.

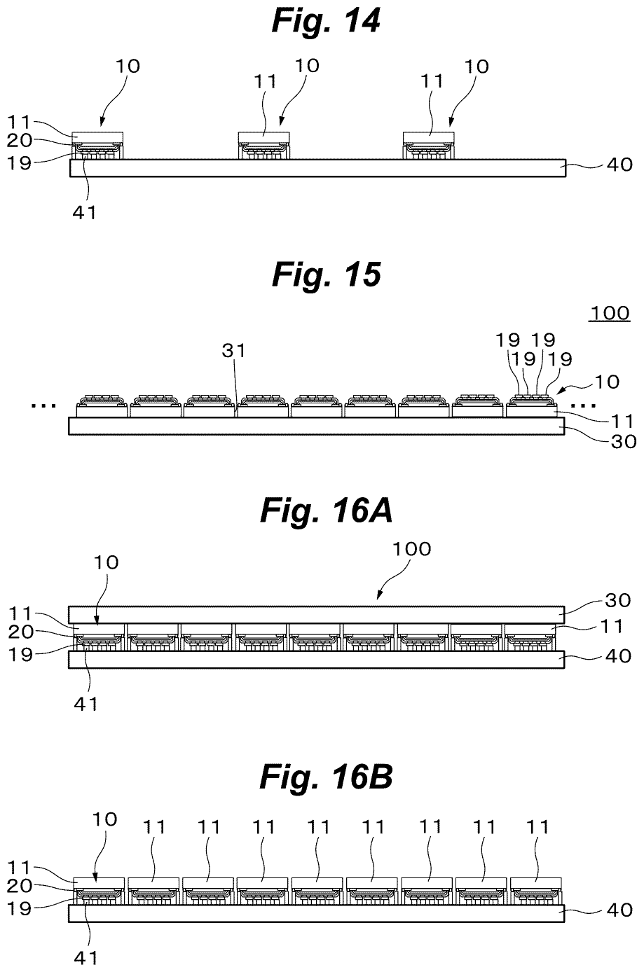

In the above manner, the micro LED chips 10 are manufactured in a state where they are transferred to predetermined positions on the secondary substrate 40, as shown in FIG. 14. FIG. 14 shows, as an example, a case where every third micro LED chip 10 is transferred.

According to the above-mentioned manufacturing method, it is possible to independently optimize the crystal growth parameters (pressure, growth rate, temperature, flow rate, supply ratio of raw materials, and the like during growth) of the AlGaInN-based crystal for each emission wavelength, and it is possible to grow the crystal under the crystal growth conditions that realize the maximum performance (luminous efficiency) for each emission wavelength. Since there are multiple crystal growth parameters, the manufacturing method that can independently optimize each of the parameters for each wavelength is very advantageous in improving the luminous efficiency.

As described above, according to the first embodiment, the light emitting layers 14, 15, 16 on the upper surface of the GaN layer 13 where light emission mainly occurs are completely separated from the dry etched portion when forming the micro LED chip 10 and unaffected by etching damage. Also, the current flowing between the p-side electrode 19 and the n-side electrode 20 is concentrated in the light emitting layers 14, 15, 16 on the upper surface of the GaN layer 13 due to the shape of the p-type GaN layer 17. It is possible to maintain a high electron-hole recombination probability in the light emitting layers 14, 15, 16 on the upper surface of the GaN layer 13, thereby achieving high luminous efficiency. Moreover, the micro LED chip 10 can be manufactured easily and at low cost using conventionally known techniques. Moreover, the micro LED chip 10 has the blue light-emitting AlGaInN-based LED structure B, the green light-emitting AlGaInN-based LED structure G and the red light-emitting AlGaInN-based LED structure R on the n-type GaN layer 11. It is possible to emit blue, green, and red light from one chip. A high-performance micro LED display can be realized using this high-performance micro LED chip 10, and high-performance XR glasses can be realized using this micro LED display. In addition, in the micro LED chip 10, each of the blue light-emitting AlGaInN-based LED structure B, the green light-emitting AlGaInN-based LED structure G and the red light-emitting AlGaInN-based LED structure R has four p-side electrodes 19 that can be controlled independently, so even if millions to tens of millions of micro LED chips are transferred and assembled at once, eliminating inspection of each individual chip (100% inspection), the pixel can be repaired by separating the defective part due to the disconnection, a high manufacturing yield of the micro LED display can be ensured.

### The Second Embodiment

### [Micro LED Chip Transfer Substrate]

FIG. 15 is a cross-sectional view showing a micro LED chip transfer substrate 100. As shown in FIG. 15, the micro LED chip transfer substrate 100 is provided with a large number of chip regions surrounded by separation grooves 31 in a two-dimensional array as shown in FIG. 11A and FIG. 11B.

### [Manufacturing Method of the Micro LED Chip Transfer Substrate]

This micro LED chip transfer substrate 100 can be manufactured by carrying out the micro LED chip manufacturing method according to the first embodiment up to the step of forming the separation grooves 31.

### [Method of Using the Micro LED Chip Transfer Substrate]

In the same manner as in the manufacturing method of the first embodiment, the micro LED chip transfer substrate 100 is bonded to the secondary substrate 40 as shown in FIG. 16A, and then a laser beam is irradiated to transfer the micro LED chip 10 to a predetermined position on the secondary substrate 40 as shown in FIG. 16B.

According to the second embodiment, by using the micro LED chip transfer substrate 100, a large number of micro LED chips 10 according to the first embodiment can be transferred to the secondary substrate 40 at once.

### The Third Embodiment

### [Micro LED Chip]

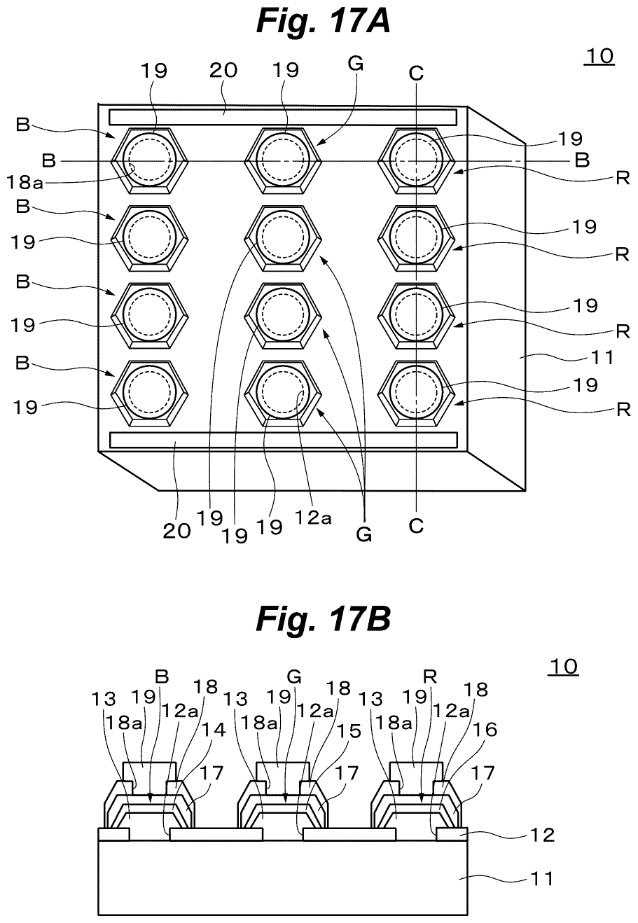

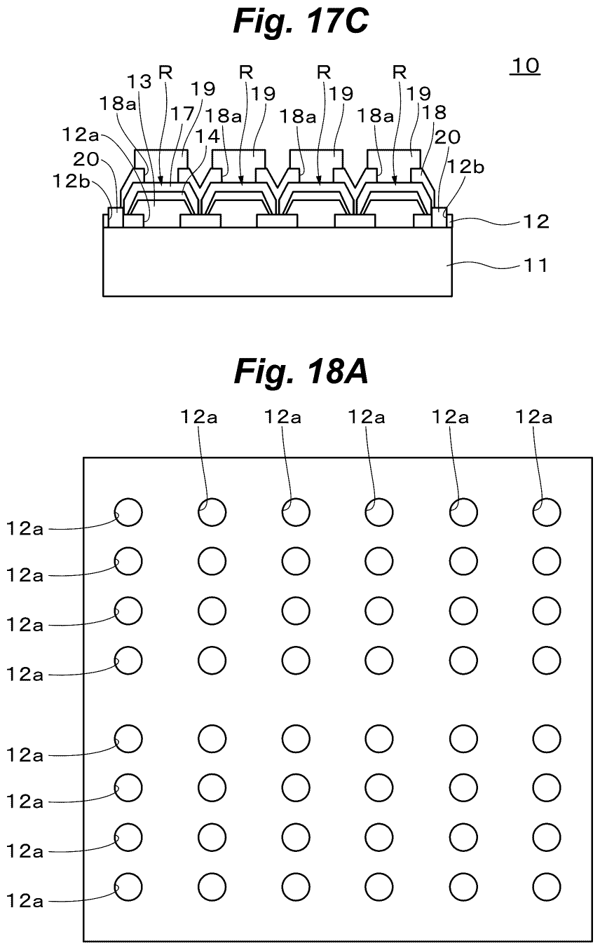

FIG. 17A, FIG. 17B and FIG. 17C show a micro LED chip 10 according to the third embodiment, in which FIG. 17A is a perspective view, FIG. 17B is a cross-sectional view taken along the B-B line in FIG. 17A, and FIG. 17C is a cross-sectional view taken along the C-C line in FIG. 17A. As shown in FIG. 17A, FIG. 17B and FIG. 17C, in the micro LED chip 10, the insulating film 12 is provided on the n-type GaN layer 11. In this case, the insulating film 12 includes a plurality of (here, four as an example) circular openings 12a that are provided in a row at equal intervals at positions corresponding to the elongated rectangular openings 12a in the first embodiment. Then, the island-shaped truncated hexagonal pyramid-shaped GaN layer 13 is provided on the n-type GaN layer 11 at each opening 12a so as to extend on the SiO₂ film 12. In a portion where the blue light-emitting AlGaInN-based LED structure B is formed, the light emitting layer 14 is provided in an island shape along the upper surface and side surfaces (slope surfaces) of the GaN layer 13, the p-type GaN layer 17 is provided to cover the light emitting layer 14, the insulating film 18 is provided to cover the p-type GaN layer 17, and the p-side electrode 19 is provided on the p-type GaN layer 17 through the contact hole 18a provided in the insulating film 18. Similarly, in a portion forming the green light-emitting AlGaInN-based LED structure G, the light-emitting layer 15 is provided in an island shape along the upper surface and side surfaces (slope surfaces) of the GaN layer 13, the p-type GaN layer 17 is provided to cover the light emitting layer 15, the insulating film 18 is provided to cover the p-type GaN layer 17, and the p-side electrode 19 is formed on the p-type GaN layer 17 through the contact hole 18a provided in the insulating film 18. In addition, in a portion where the red light-emitting AlGaInN-based LED structure R is formed, the light emitting layer 16 is provided in an island shape along the upper surface and side surfaces (slope surfaces) of the GaN layer 13, the p-type GaN layer 17 is provided to cover the light emitting layer 16, the insulating film 18 is provided to cover the p-type GaN layer 17, and the p-side electrode 19 is provided on the p-type GaN layer 17 through the contact hole 18a provided in the insulating film 18. In this case, N_{b} of the blue light-emitting AlGaInN-based LED structure B=4, N_{g} of the green light-emitting AlGaInN-based LED structure G=4, Nᵣ of the red light-emitting AlGaInN-based LED structure R=4, and the number of the p-side electrodes 19 is Nₚ=1 in all of the blue light-emitting AlGaInN-based LED structure B, the green light-emitting AlGaInN-based LED structure G, and the red light-emitting AlGaInN-based LED structure R, Nₚ×N_{b}≥2, Nₚ×N_{g}≥2, and Nₚ×Nᵣ≥2 are satisfied. The micro LED chip 10 is the same as the micro LED chip 10 according to the first embodiment except for the above.

### [Manufacturing Method of Micro LED Chip]

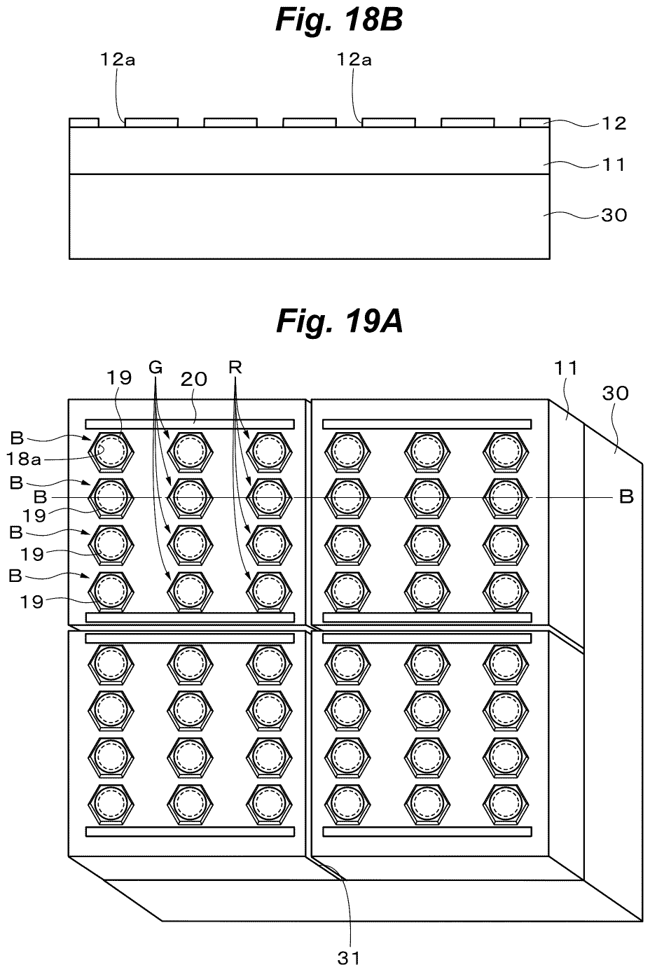

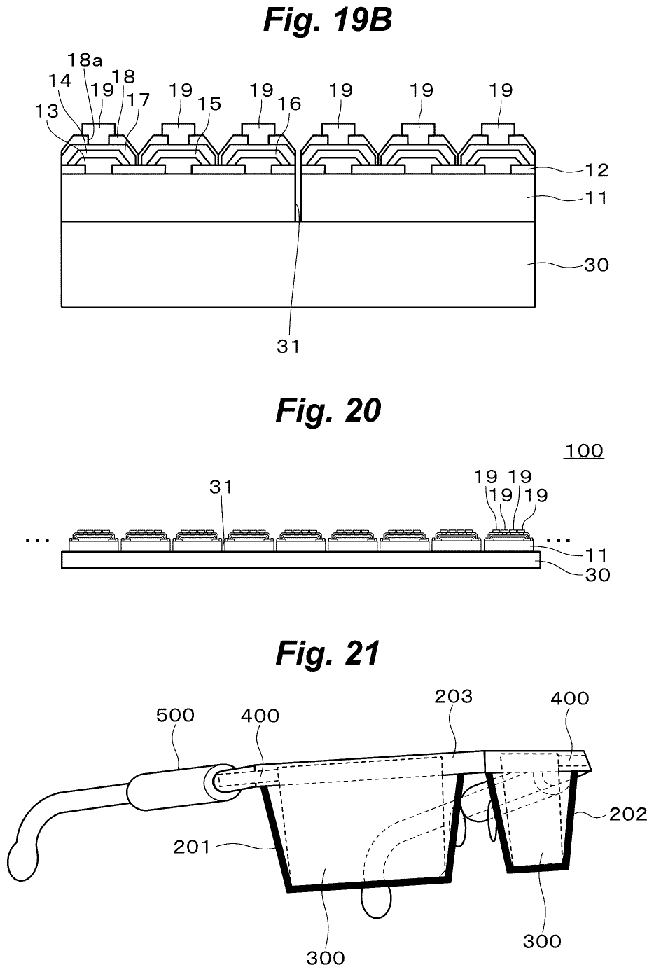

First, as shown in FIG. 18A and FIG. 18B, in the same manner as in the manufacturing method of the first embodiment, the n-type GaN layer 11 is grown on the sapphire substrate 30, the insulating film 12 is formed thereon, and then the insulating film 12 is patterned to form the circular opening 12a. Here, FIG. 18A is a plan view, and FIG. 18B is a cross-sectional view. Next, as shown in FIG. 19A and FIG. 19B, the process proceeds in the same manner as in the manufacturing method of the first embodiment, and the island-shaped truncated hexagonal pyramid-shaped GaN layer 13 is grown on the n-type GaN layer 11 in the opening 12a of the insulating film 12, and the blue light-emitting AlGaInN-based LED structure B, the green light-emitting AlGaInN-based LED structure G, and the red light-emitting AlGaInN-based LED structure R are formed, and finally, the micro LED chip 10 is manufactured through transfer to the secondary substrate 40. Here, FIG. 19A is a plan view, and FIG. 19B is a cross-sectional view.

According to the third embodiment, it is possible to obtain the same advantages as those of the first embodiment.

### The Fourth Embodiment

### [Micro LED Chip Transfer Substrate]

FIG. 20 is a cross-sectional view showing the micro LED chip transfer substrate 100. As shown in FIG. 20, the micro LED chip transfer substrate 100 has a large number of chip regions surrounded by the separation grooves 31 that are arranged in a two-dimensional array as shown in FIG. 19A and FIG. 19B.

### [Manufacturing Method of the Micro LED Chip Transfer Substrate]

This micro LED chip transfer substrate 100 can be manufactured by carrying out the micro LED chip manufacturing method according to the third embodiment up to the step of forming the separation grooves 31.

### [Method of Using the Micro LED Chip Transfer Substrate]

Similar to the manufacturing method of the third embodiment, after bonding the micro LED chip transfer substrate 100 to the secondary substrate 40, the micro LED chip 10 is transferred to the secondary substrate 40 to a predetermined position by laser beam irradiation.

According to the fourth embodiment, by using the micro LED chip transfer substrate 100, a large number of micro LED chips 10 according to the third embodiment can be transferred to the secondary substrate 40 at once.

### The Fifth Embodiment

### [XR Glasses]

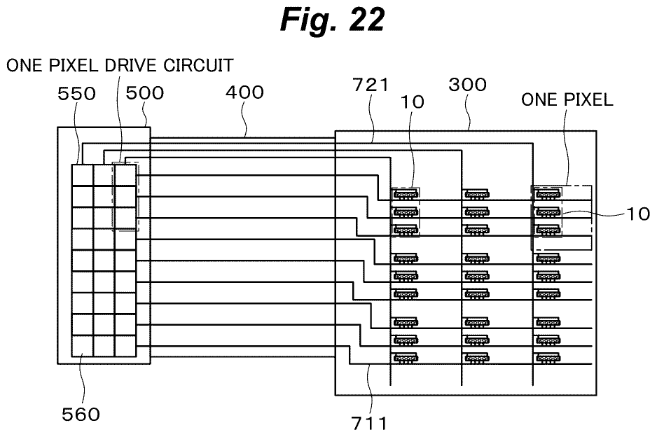

FIG. 21 shows XR glasses according to the fifth embodiment. As shown in FIG. 21, in the XR glasses, a display section 300 in which a large number of micro LED chips 10 are mounted in a two-dimensional array is attached to the inner surface of the part of windshield parts 201, 202 that face the pupils of the user's eyes when the user wears the XR glasses. The material of the windshield parts 201, 202 is generally glass or plastic, but depending on the case, they may have a power as a lens for nearsightedness or farsightedness. Since the distance between the display section 300 and the pupils of the user's eyes when the user wears the XR glasses is as short as a dozen mm, at least one lens (not shown) is attached between the pupils and the light emitting surface of the display section 300 to adjust the focal distance and adjusted to focus on each pixel at a distance that is comfortable for the eyes. The lens may be a convex lens or a Fresnel lens that covers the entire display section 300, or a microlens may be provided for each pixel. Further, the optical system may be configured by combining not only one lens but also a plurality of lenses. The display section 300 is configured to be smaller than the windshield sections 201, 202. The display section 300 is connected via a flexible printed circuit 400 to a drive circuit board 550 (see FIG. 22) made of Si-CMOSIC mounted on a printed circuit board 500. The flexible printed circuit 400 and the printed circuit board 500 are mounted on a frame 203. The printed circuit board 500 is attached to the ear hook portion of the frame 203 in a wrapped state. FIG. 22 shows an overall view of the display section 300, the flexible printed circuit 400, and the printed circuit board 500.

On the drive circuit board 550, drive circuits 560 configured by CMOS circuits are provided in a two-dimensional array. In FIG. 22, one pixel drive circuit is configured by three drive circuits 560 adjacent to each other shown by dashed-and-dotted lines on the drive circuit board 550. The size of the drive circuit 560 is selected as necessary, and is not particularly limited, but is, for example, about 24 μm square.

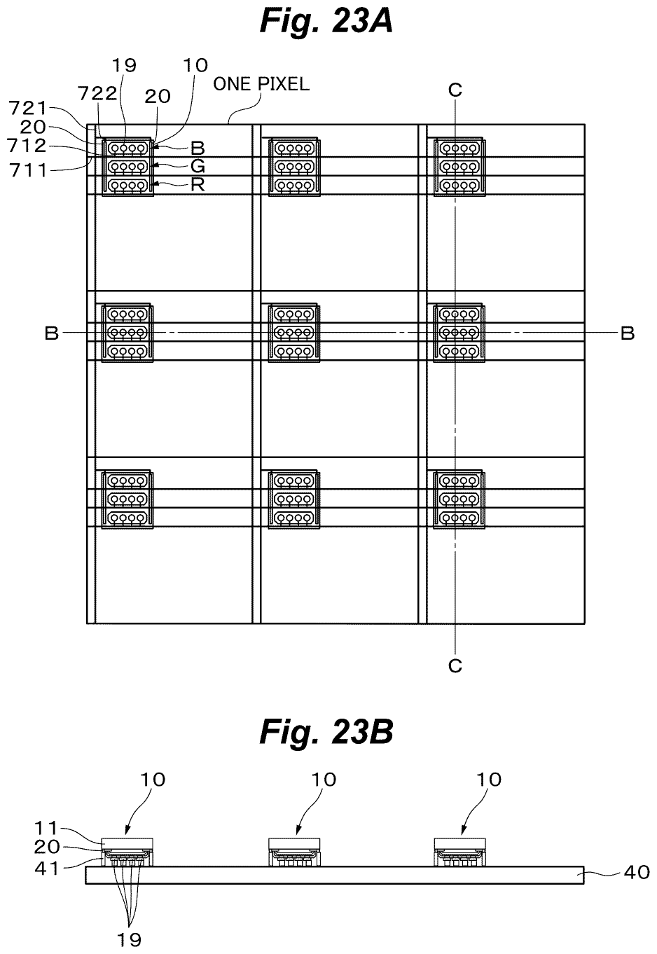

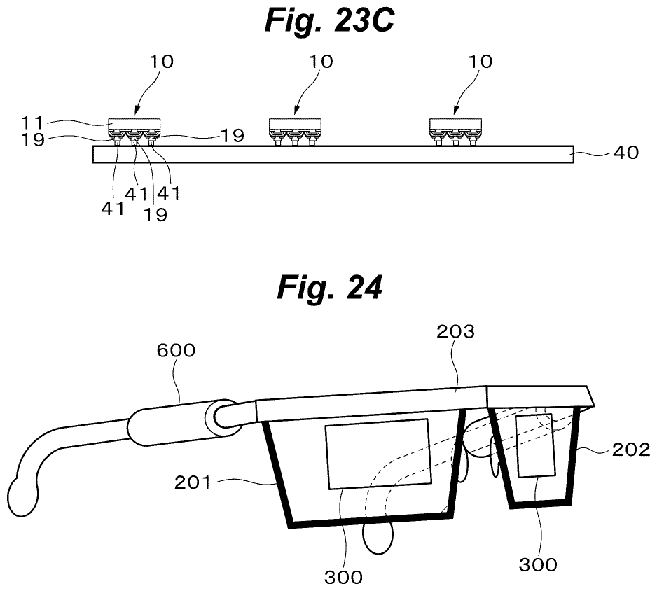

Details of the display section 300 are shown in FIG. 23A. FIG. 23B and FIG. 23C are cross-sectional views along the B-B line and the C-C line in FIG. 23A, respectively. As shown in FIG. 22, FIG. 23A, FIG. 23B and FIG. 23C, a large number of micro LED chips 10 having the blue light-emitting AlGaInN-based LED structure B, the green light-emitting AlGaInN-based LED structure G and the red light-emitting AlGaInN-based LED structure R are arranged in a two-dimensional array in the display section 300 (see FIG. 1A, FIG. 1B and FIG. 1C for details of the micro LED chip 10). Four branch wirings 712 branched from a p-side wiring 711 connected to the drive circuit 560 of the drive circuit board 550 via the flexible printed circuit 400 per micro LED chip 10 are connected to the four p-side electrodes 19 of each of the blue light-emitting AlGaInN-based LED structure B, the green light-emitting AlGaInN-based LED structure G and the red light-emitting AlGaInN-based LED structure R. Although not shown, a thin film fuse is provided in the middle of the branch wiring 712, and when excessive current is applied due to a leak defect of the p-side electrode 19, the thin film fuse melts to disconnect the branch wiring 712. Similarly, the branch wiring 722 branched from the n-side wiring 721 connected to the drive circuit 560 of the drive circuit board 550 via the flexible printed circuit 400 is connected to the n-side electrodes 20 at both ends of the micro LED chip 10. The size of one pixel shown in FIG. 23A is, for example, 4.2 μm×4.2 μm. This corresponds to a pixel density of 6000 ppi. If the chip size of the micro LED chip 10 is, for example, 1.6 μm×1.6 μm, the aperture ratio is approximately 85%. A power supply (battery), a control circuit, and the like of the display section 300 and the drive circuit board 550 are provided in the ear hook part, windshield parts 201, 202, and the like of the frame 203 of the XR glasses. The micro LED chip 10 can be easily mounted on the display section 300 by using the micro LED chip transfer substrate 100 according to the second embodiment.

According to the fifth embodiment, the following advantages can be obtained. That is, the display section 300 for the XR glasses has the blue light-emitting AlGaInN-based LED structure B, the green light-emitting AlGaInN-based LED structure G and the red light-emitting AlGaInN-based LED structure R, and the micro LED chips 10 capable of emitting blue light, green light, and red light are arranged in a two-dimensional array, so that the area of the micro LED chips 10 per pixel of the display section 300 can be extremely small, and the aperture ratio of one pixel can be greatly increased. In addition, a pixel density of tens of thousands of PPI can be easily realized. Furthermore, the mounting of the micro LED chips 10 can be quickly and easily performed using the micro LED chip transfer substrate 100. In addition, in the XR glasses, since the printed circuit board 500 on which the driving circuit board 550 is mounted and the display section 300 are connected to each other by the flexible printed circuit 400, it is sufficient to manufacture the array of the driving circuit 560 of the driving circuit board 550 at a lower density. As a result, high-performance XR glasses can be easily realized.

### The Sixth Embodiment

### [XR Glasses]

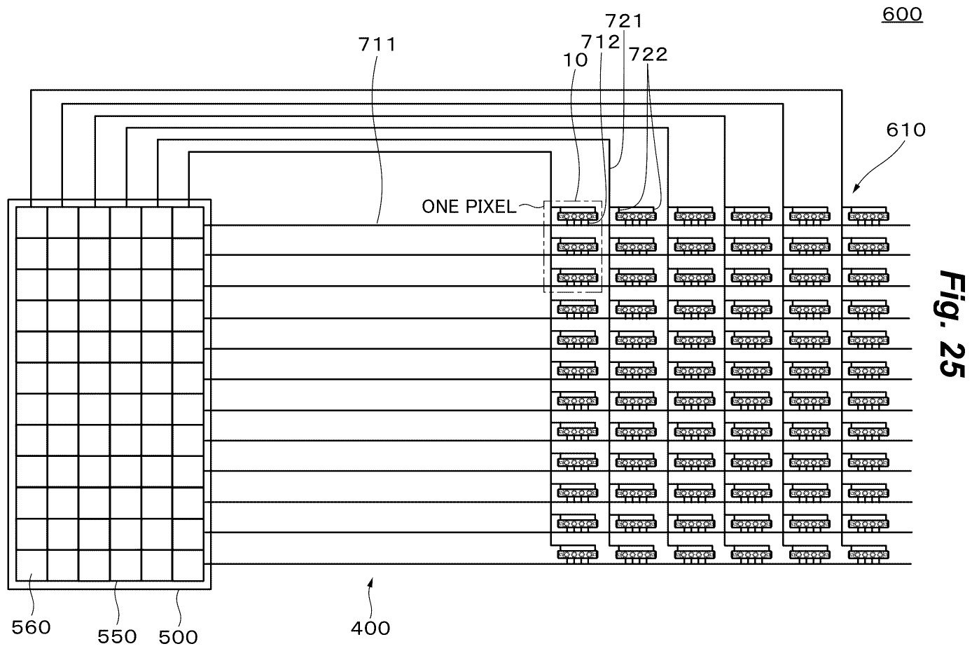

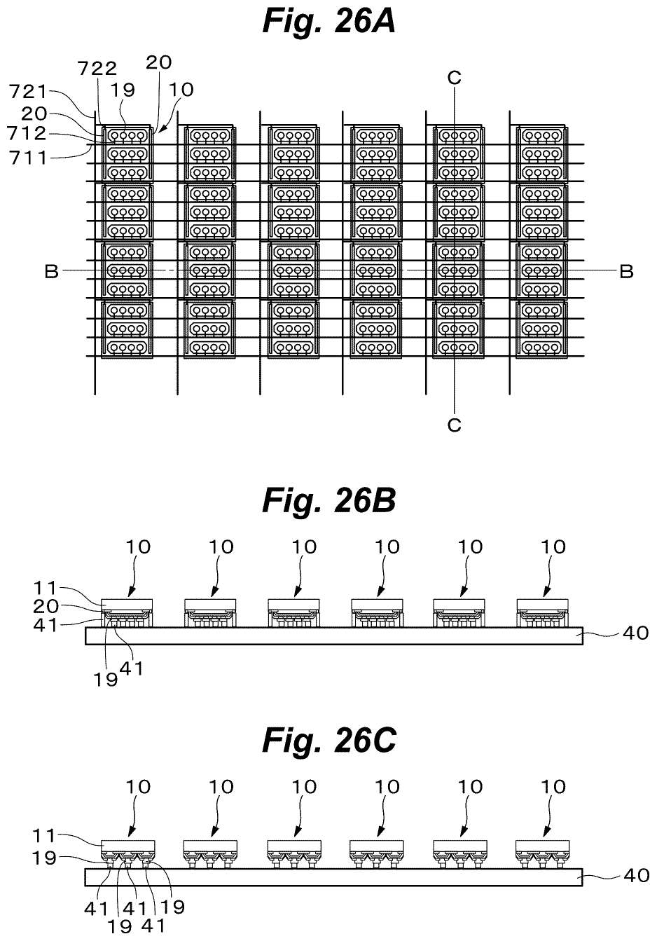

FIG. 24 shows XR glasses according to the sixth embodiment. As shown in FIG. 24, in the XR glasses, a light engine 600 is provided to the ear hook of the frame 203 in a wrapped state. FIG. 25 shows a developed view of the light engine 600. As shown in FIG. 25, in the light engine 600, an LED array section 610 in which a large number of micro LED chips 10 are mounted in a two-dimensional array and the driving circuit board 550 made of a Si-CMOSIC mounted on the printed circuit board 500 are connected by the flexible printed circuit 400. An optical waveguide (not shown) is provided from the light emitting section of the light engine 600 through the ear hooks of the frame 203 to the inner surface of the part of the windshield sections 201, 202 facing the pupils of the user's eyes when the user wears the XR glasses. Then, light emitted from the micro LED chips 10 of the LED array section 610 of the light engine 600 enters one end of the optical waveguide through a lens (not shown), and is repeatedly totally reflected within the optical waveguide so that light is emitted to the outside from the other end of the optical waveguide, and the other end of the optical waveguide constitutes the display section 300. In the LED array section 610, the micro LED chips 10 are connected by simple matrix wiring consisting of p-side wiring 711 and n-side wiring 721 arranged vertically and horizontally. Details of the LED array section 610 are shown in FIG. 26A. FIG. 26B and FIG. 26C are cross-sectional views taken along the B-B line and the C-C line in FIG. 26A, respectively. The micro LED chips 10 of the LED array section 610 can be easily mounted using the micro LED chip transfer substrate 100.

According to the sixth embodiment, since an optical waveguide is used in the display section 300, there is no need to ensure an aperture ratio, and the light engine 600 can be made compact by arranging the micro LED chips 10 in a high density in the LED array section 610.

### The Seventh Embodiment

### [XR Glasses]

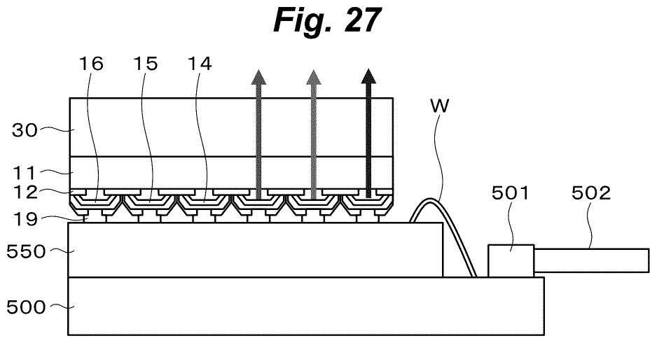

In XR glasses according to the seventh embodiment, the configuration of the light engine 600 is different from the XR glasses according to the sixth embodiment. FIG. 27 shows the light engine 600 used in the XR glasses according to the seventh embodiment.

In the first to sixth embodiments, the sapphire substrate 30 used in the manufacture of the micro LED chip 10 is finally peeled off, but since the sapphire substrate 30 is transparent to visible light, it is possible to use it without peeling it off. Therefore, in the XR glasses according to the seventh embodiment, after performing the steps before the step of forming the separation groove 31 on the sapphire substrate 30, the sapphire substrate 30 is polished from the back surface to be thinned. For example, the sapphire substrate 30 having a thickness of 400 μm is used, and the sapphire substrate 30 is thinned to a thickness of 100 μm or less, for example, 80 μm. Next, the sapphire substrate 30 is cut to a size including the required number of pixels, and as shown in FIG. 27, the sapphire substrate 30 of a predetermined size thus cut is bonded to the driving circuit board 550 consisting of a Si-CMOSIC mounted on the printed circuit board 500 as a secondary board. The printed circuit board 500 and the driving circuit board 550 are bonded with wires W. In this case, the LED array section 610 is bonded to the driving circuit board 550. The printed circuit board 500 is connected to a power source and a control circuit via wiring 502 connected to a terminal 501. As in the sixth embodiment, light emitted from the micro LED chips 10 of the LED array section 610 of the light engine 600 enters one end of the optical waveguide via a lens (not shown), and is repeatedly totally reflected within the optical waveguide before being emitted to the outside from the other end of the optical waveguide. The other end of the optical waveguide constitutes the display section 300.

According to the seventh embodiment, the same advantages as the fifth and sixth embodiments can be obtained.

Heretofore, embodiments of the present invention have been explained specifically. However, the present invention is not limited to these embodiments, but contemplates various changes and modifications based on the technical idea of the present invention.

For example, numerical numbers, structures, shapes, materials, methods and the like presented in the aforementioned embodiments are only examples, and the different numerical numbers, structures, shapes, materials, methods and the like may be used as necessary.

### EXPLANATION OF REFERENCE NUMERALS

10 vertical micro LED chip
11 n-type GaN layer
12 insulating film
12a opening
13 GaN layer
14, 15, 16 light emitting layer
17 p-type GaN layer
18 insulating film
18a contact hole
19 p-side electrode
20 n-side electrode
30 C-plane sapphire substrate
40 secondary substrate
41 solder layer
B Blue light-emitting AlGaInN-based LED structure
G Green light-emitting AlGaInN-based LED structure
R Red light-emitting AlGaInN-based LED structure

1. A micro light emitting diode chip, comprising:
at least one blue light-emitting AlGaInN-based light emitting diode structure, at least one green light-emitting AlGaInN-based light emitting diode structure and at least one red light-emitting AlGaInN-based light-emitting diode structure on an n-type GaN layer,
the blue light-emitting AlGaInN-based light emitting diode structure, the green light-emitting AlGaInN-based light emitting diode structure and the red light-emitting AlGaInN-based light emitting diode structure comprising:
an insulating film having at least one opening provided on the n-type GaN layer,
a truncated polygonal pyramid-shaped GaN layer provided on the n-type GaN layer in the opening of the insulating film,
a light emitting layer provided along the upper surface and side surfaces of the truncated polygonal pyramid-shaped GaN layer,
a p-type GaN layer provided to cover the light emitting layer,
one or a plurality of mutually separated p-side electrodes provided on the upper surface of the p-type GaN layer; and
at least one n-side electrode provided on the n-type GaN layer in a portion where the truncated polygonal pyramid-shaped GaN layer is not provided,
$${N}_{p} \times {N}_{b} \geq 2 , {N}_{p} \times {N}_{g} \geq 2 and {N}_{p} \times {N}_{r} \geq 2$$
being satisfied if the respective numbers of the blue light-emitting AlGaInN-based light emitting diode structures, the green light-emitting AlGaInN-based light emitting diode structures and the red light-emitting AlGaInN-based light emitting diode structures included in the entire micro light emitting diode chip are denoted as N_{b}, N_{g} and Nᵣ and the numbers of the p-side electrodes provided on the upper surface of the p-type GaN layer of each of the blue light-emitting AlGaInN-based light emitting diode structure, the green light-emitting AlGaInN-based light emitting diode structure and the red light-emitting AlGaInN-based light emitting diode structure is denoted as Nₚ.

2. The micro light emitting diode chip according to claim 1, wherein the thickness of the p-type GaN layer above the upper surface of the truncated polygonal pyramid-shaped GaN layer is smaller than the thickness of the p-type GaN layer above the side surfaces of the truncated polygonal pyramid-shaped GaN layer, and light is mainly emitted from the light emitting layer on the upper surface of the truncated polygonal pyramid-shaped GaN layer.

3. A micro light emitting diode chip transfer substrate, comprising:
chip regions which are arranged in a two-dimensional array on an n-type GaN layer provided on a substrate, each of the chip regions including at least one blue light-emitting AlGaInN-based light emitting diode structure, at least one green light-emitting AlGaInN-based light emitting diode structure and at least one red light-emitting AlGaInN-based light emitting diode structure, the blue light-emitting AlGaInN-based light emitting diode structure, the green light-emitting AlGaInN-based light emitting diode structure and the red light-emitting AlGaInN-based light emitting diode structure comprising:
an insulating film having at least one opening provided on the n-type GaN layer,
a truncated polygonal pyramid-shaped GaN layer provided on the n-type GaN layer in the opening of the insulating film,
a light emitting layer provided along the upper surface and side surfaces of the truncated polygonal pyramid-shaped GaN layer,
a p-type GaN layer provided to cover the light emitting layer,
one or a plurality of mutually separated p-side electrodes provided on the upper surface of the p-type GaN layer; and
at least one n-side electrode provided on the n-type GaN layer in a portion where the truncated polygonal pyramid-shaped GaN layer is not provided,
$${N}_{p} \times {N}_{b} \geq 2 , {N}_{p} \times {N}_{g} \geq 2 and {N}_{p} \times {N}_{r} \geq 2$$
being satisfied if the respective numbers of the blue light-emitting AlGaInN-based light emitting diode structures, the green light-emitting AlGaInN-based light emitting diode structures and the red light-emitting AlGaInN-based light emitting diode structures included in the entire chip region are denoted as N_{b}, N_{g} and Nᵣ and the numbers of the p-side electrodes provided on the upper surface of the p-type GaN layer of each of the blue light-emitting AlGaInN-based light emitting diode structure, the green light-emitting AlGaInN-based light emitting diode structure and the red light-emitting AlGaInN-based light emitting diode structure is denoted as Nₚ,
the chip region being defined by a separation groove that separates the n-type GaN layer.

4. A micro light emitting diode display, comprising:
a display section in which a plurality of micro light emitting diode chips are mounted in a two-dimensional array,
a drive circuit section in which a plurality of drive circuits which can be independently controlled and driven are provided in a two-dimensional array; and
a wiring circuit which wires the display section and the drive circuit section,
the micro light-emitting diode chip being a micro light emitting diode chip comprising:
at least one blue light-emitting AlGaInN-based light emitting diode structure, at least one green light-emitting AlGaInN-based light emitting diode structure and at least one red light-emitting AlGaInN-based light emitting diode structure on an n-type GaN layer,
the blue light-emitting AlGaInN-based light emitting diode structure, the green light-emitting AlGaInN-based light emitting diode structure and the red light-emitting AlGaInN-based light emitting diode structure comprising:
an insulating film having at least one opening provided on the n-type GaN layer,
a truncated polygonal pyramid-shaped GaN layer provided on the n-type GaN layer in the opening of the insulating film,
a light emitting layer provided along the upper surface and side surfaces of the truncated polygonal pyramid-shaped GaN layer,
a p-type GaN layer provided to cover the light emitting layer,
one or a plurality of mutually separated p-side electrodes provided on the upper surface of the p-type GaN layer; and
at least one n-side electrode provided on the n-type GaN layer in a portion where the truncated polygonal pyramid-shaped GaN layer is not provided,
$${N}_{p} \times {N}_{b} \geq 2 , {N}_{p} \times {N}_{g} \geq 2 and {N}_{p} \times {N}_{r} \geq 2$$
being satisfied if the respective numbers of the blue light-emitting AlGaInN-based light emitting diode structures, the green light-emitting AlGaInN-based light emitting diode structures and the red light-emitting AlGaInN-based light emitting diode structures included in the entire micro light emitting diode chip are denoted as N_{b}, N_{g} and Nᵣ and the numbers of the p-side electrodes provided on the upper surface of the p-type GaN layer of each of the blue light-emitting AlGaInN-based light emitting diode structure, the green light-emitting AlGaInN-based light emitting diode structure and the red light-emitting AlGaInN-based light emitting diode structure is denoted as Nₚ.

5. The micro light emitting diode display according to claim 4, wherein a plurality of p-side electrodes are provided separately from one another for each of the blue light-emitting AlGaInN-based light emitting diode structure, the green light-emitting AlGaInN-based light emitting diode structure and the red light-emitting AlGaInN-based light emitting diode structure, and at least one n-side electrode is provided,
wherein each of a plurality of branch wirings branched from a first trunk wiring connected to the drive circuit of the drive circuit section via wiring of the wiring circuit and each of the p-side electrodes are electrically connected each other and a second trunk wiring connected to the drive circuit of the drive circuit section via wiring of the wiring circuit and the n-side electrodes are electrically connected each other in each of the micro light emitting chip.

6. XR glasses comprising:
a display,
the display comprising:
a display section in which a plurality of micro light emitting diode chips are mounted in a two-dimensional array,
a drive circuit board on which a plurality of drive circuits which can be independently controlled and driven are provided in a two-dimensional array; and
a flexible printed circuit wiring the display section and the drive circuit board,
the micro light emitting diode chip being a micro light emitting diode chip, comprising:
at least one blue light-emitting AlGaInN-based light emitting diode structure, at least one green light-emitting AlGaInN-based light emitting diode structure and at least one red light-emitting AlGaInN-based light emitting diode structure on an n-type GaN layer,
the blue light-emitting AlGaInN-based light emitting diode structure, the green light-emitting AlGaInN-based light emitting diode structure and the red light-emitting AlGaInN-based light emitting diode structure comprising:
an insulating film having at least one opening provided on the n-type GaN layer,
a truncated polygonal pyramid-shaped GaN layer provided on the n-type GaN layer in the opening of the insulating film, a light emitting layer provided along the upper surface and side surfaces of the truncated polygonal pyramid-shaped GaN layer,
a p-type GaN layer provided to cover the light emitting layer,
one or a plurality of mutually separated p-side electrodes provided on the upper surface of the p-type GaN layer; and
at least one n-side electrode provided on the n-type GaN layer in a portion where the truncated polygonal pyramid-shaped GaN layer is not provided,
$${N}_{p} \times {N}_{b} \geq 2 , {N}_{p} \times {N}_{g} \geq 2 and {N}_{p} \times {N}_{r} \geq 2$$
being satisfied if the respective numbers of the blue light-emitting AlGaInN-based light emitting diode structures, the green light-emitting AlGaInN-based light emitting diode structures and the red light-emitting AlGaInN-based light emitting diode structures included in the entire micro light emitting diode chip are denoted as N_{b}, N_{g} and Nᵣ and the numbers of the p-side electrodes provided on the upper surface of the p-type GaN layer of each of the blue light-emitting AlGaInN-based light emitting diode structure, the green light-emitting AlGaInN-based light emitting diode structure and the red light-emitting AlGaInN-based light emitting diode structure is denoted as Nₚ,
the display section being attached to the inside surface of the windshield section,
the drive circuit board being attached to the ear hook part of the frame,
the flexible printed circuit being attached to the frame.

7. The XR glasses according to claim 6, wherein a plurality of p-side electrodes are provided separately from one another for each of the blue light-emitting AlGaInN-based light emitting diode structure, the green light-emitting AlGaInN-based light emitting diode structure and the red light-emitting AlGaInN-based light emitting diode structure, and at least one n-side electrode is provided,
wherein each of a plurality of branch wirings branched from a first trunk wiring connected to the drive circuit of the drive circuit board via wiring of the wiring circuit and each of the p-side electrodes are electrically connected each other and a second trunk wiring connected to the drive circuit of the drive circuit board via wiring of the wiring circuit and the n-side electrodes are electrically connected each other in each of the micro light emitting chip.
